(19) United States
(12) Patent Application Publication
(10) Pub. No.: US 2025/0354254 A1
(43) Pub. Date: Nov. 20, 2025

(54) DEPOSITION APPARATUS, METHOD OF DRIVING THE SAME, AND ELECTRONIC DEVICE

(71) Applicant: Samsung Display Co., LTD., Yongin-si (KR)

(72) Inventors: Sang Keun LEE, Yongin-si (KR); Seung Ho MYOUNG, Yongin-si (KR); Byung Hun SUNG, Yongin-si (KR); Seung Geun YUN, Yongin-si (KR)

(21) Appl. No.: 19/072,648

(22) Filed: Mar. 6, 2025

(30) Foreign Application Priority Data
May 20, 2024 (KR) 10-2024-0065404

(51) Int. Cl. C23C 14/54; C23C 14/50

(52) U.S. Cl. CPC C23C 14/54; C23C 14/50

(57) ABSTRACT

A deposition apparatus includes: a chamber including an internal space settable to either atmospheric conditions or vacuum conditions; a substrate support in the internal space of the chamber and configured to support a substrate; a first driver configured to reciprocate the substrate support in a first direction and a direction opposite to the first direction; an electrostatic chuck spaced apart from the substrate support in the first direction; a displacement sensor installed in the electrostatic chuck, and configured to measure a first spacing distance from the substrate support under the atmospheric conditions and a second spacing distance from the substrate support under the vacuum conditions; and a controller configured to adjust a position of the substrate support based on a displacement difference between the first spacing distance and the second spacing distance.

### CROSS-REFERENCE TO RELATED APPLICATION

The present application claims priority to and the benefit of Korean Patent Application Number 10-2024-0065404, filed on May 20, 2024, in the Korea Intellectual Property Office, the entire disclosure of which is incorporated herein by reference.

### BACKGROUND

### 1. Field

Aspects of some embodiments of the present disclosure relate to a deposition apparatus and a method of driving the deposition apparatus.

### 2. Description of Related Art

Recently, electronic devices such as information smartphones, tablet PCs, notebook computers, and smart televisions have been developed. Such electronic devices may have a display device for providing information. To fabricate the display device, several iterations of processes may be performed, including a thin-film deposition provided to form a thin film of a certain material on a substrate surface, a photolithography process provided to expose a selected portion of the thin film, and a dry or wet etching process provided to pattern the thin film into a desired shape by removing the exposed portion of the thin film. Among the aforementioned processes, the dry etching process, the thin-film deposition, and the like are may be carried out in a closed process chamber. Each process chamber may be equipped with an electrostatic chuck provided to hold the substrate in place, a cooler provided to control a process temperature, and the like.

The above information disclosed in this Background section is only for enhancement of understanding of the background and therefore the information discussed in this Background section does not necessarily constitute prior art.

### SUMMARY

Aspects of some embodiments of the present disclosure include a deposition apparatus and a method of driving the deposition apparatus capable of relatively stably adsorbing a substrate to an electrostatic chuck without the substrate being damaged or broken, even when internal environment in a chamber changes from atmospheric pressure to vacuum.

However, characteristics of embodiments according to the present disclosure are not limited to the above-described characteristics, and various modifications are possible without departing from the spirit and scope of embodiments according to the present disclosure.

According to some embodiments of the present disclosure, a deposition apparatus includes: a chamber including an internal space settable to either atmospheric conditions or vacuum conditions; a substrate support in the internal space of the chamber and configured to support a substrate; a first driver configured to reciprocate the substrate support in a first direction and a direction opposite to the first direction; an electrostatic chuck spaced apart from the substrate support in the first direction; a displacement sensor installed in the electrostatic chuck, and configured to measure a first spacing distance from the substrate support under the atmospheric conditions and a second spacing distance from the substrate support under the vacuum conditions; and a controller configured to adjust a position of the substrate support based on a displacement difference between the first spacing distance and the second spacing distance.

According to some embodiments, in the case where the second spacing distance is less than the first spacing distance, the controller may adjust the position of the substrate support in a direction away from the electrostatic chuck.

According to some embodiments, a position variation of the substrate support may be equal to or greater than the displacement difference.

According to some embodiments, in the case where the second spacing distance is greater than the first spacing distance, the controller may adjust the position of the substrate support in a direction approaching the electrostatic chuck.

According to some embodiments, the position variation of the substrate support may be less than or equal to the displacement difference.

According to some embodiments, the substrate support may include: a plurality of first holders configured to support a first area of the substrate; and a plurality of second holders configured to support a second area of the substrate distinct from the first area.

According to some embodiments, the displacement sensor may include: a first sub-displacement sensor overlapping at least one of the first holders in a plan view; and a second sub-displacement sensor overlapping at least one of the second holders in a plan view. According to some embodiments, the first spacing distance may include: a 1_1-th sub-spacing distance measured by the first sub-displacement sensor and defined between the first sub-displacement sensor and the first holder; and a 1_2-th sub-spacing distance measured by the second sub-displacement sensor and defined between the second sub-displacement sensor and the second holder. According to some embodiments, the second spacing distance may include: a 2_1-th sub-spacing distance measured by the first sub-displacement sensor and defined between the first sub-displacement sensor and the first holder; and a 2_2-th sub-spacing distance measured by the second sub-displacement sensor and defined between the second sub-displacement sensor and the second holder. According to some embodiments, the displacement difference may be a larger value between a first displacement difference between the 1_1-th sub-spacing distance and the 2_1-th sub-spacing distance and a second displacement difference between the 1_2-th sub-spacing distance and the 2_2-th sub-spacing distance.

According to some embodiments, the substrate support may further include: a first bracket on which the first holders are located; and a second bracket on which the second holders are located. According to some embodiments, the first driver may include: a first sub-driver connected to the first bracket; and a second sub-driver connected to the second bracket.

According to some embodiments, the controller may transmit a first driving signal derived based on the displacement difference to the first sub-driver, and may transmit a second driving signal derived based on the displacement difference to the second sub-driver. According to some embodiments, the first sub-driver may move the first bracket in the first direction or the direction opposite to the first direction based on the first driving signal. According to some embodiments, the second sub-driver may move the second bracket in the first direction or the direction opposite to the first direction based on the second driving signal.

According to some embodiments, the displacement sensor may include: a third sub-displacement sensor configured not to overlap the first holders in a plan view; and a fourth sub-displacement sensor configured not to overlap the second holders in a plan view.

According to some embodiments, the first spacing distance may include: a 1_3-th sub-spacing distance measured by the third sub-displacement sensor and defined between the third sub-displacement sensor and one area of a dummy substrate on the first holder; and a 1_4-th sub-spacing distance measured by the fourth sub-displacement sensor and defined between the fourth sub-displacement sensor and another area of the dummy substrate on the second holder. According to some embodiments, the second spacing distance may include: a 2_3-th sub-spacing distance measured by the third sub-displacement sensor and defined between the third sub-displacement sensor and one area of the dummy substrate on the first holder; and a 2_4-th sub-spacing distance measured by the fourth sub-displacement sensor and defined between the fourth sub-displacement sensor and another area of the dummy substrate on the second holder.

According to some embodiments, the displacement difference may be a larger value between a third displacement difference between the 1_3-th sub-spacing distance and the 2_3-th sub-spacing distance and a fourth displacement difference between the 1_4-th sub-spacing distance and the 2_4-th sub-spacing distance.

According to some embodiments, the deposition apparatus may further include a pressing component configured to press a lower side of the substrate.

According to some embodiments, the pressing component may include: a plurality of first pusher pins configured to press a portion of the substrate, and a plurality of second pusher pins configured to press another portion of the substrate.

According to some embodiments, the deposition apparatus may further include a second driver configured to reciprocate the pressing component in the first direction and the direction opposite to the first direction. According to some embodiments, the pressing component may include: a third bracket on which the first pusher pins are located; and a fourth bracket on which the second push pins are located. According to some embodiments, the second driver may include: a third sub-driver connected to the third bracket; and a fourth sub-driver connected to the fourth bracket.

According to some embodiments of the present disclosure, a method of driving a deposition apparatus, includes: measuring a first spacing distance between a substrate support and a displacement sensor installed in an electrostatic chuck under atmospheric conditions; measuring a second spacing distance between the substrate support and the displacement sensor installed in the electrostatic chuck under vacuum conditions; calculating a displacement difference between the first spacing distance and the second spacing distance; and adjusting a position of the substrate support based on the displacement difference.

According to some embodiments, adjusting the position of the substrate support may include moving the position of the substrate support in a direction away from the electrostatic chuck in the case where the second spacing distance is less than the first spacing distance.

According to some embodiments, a position variation of the substrate support may be equal to or greater than the displacement difference.

According to some embodiments, adjusting the position of the substrate support may include moving the position of the substrate support in a direction approaching the electrostatic chuck in the case where the second spacing distance is greater than the first spacing distance.

According to some embodiments, a position variation of the substrate support may be less than or equal to the displacement difference.

The characteristics of embodiments according to the present disclosure may not be limited to the above, and other characteristics of embodiments according to the present disclosure will be more clearly understandable to those having ordinary skill in the art from the disclosures provided below together with accompanying drawings.

An embodiment of the disclosure may provide an electronic device including: a processor; and a display device including pixels, and configured to display images on the pixels under control of the processor. The display device may be fabricated by the method of driving a deposition apparatus.

### BRIEF DESCRIPTION OF THE DRAWINGS

FIG. 1 is a conceptual diagram schematically illustrating aspects of a deposition apparatus according to some embodiments.

FIG. 2 is a plan view illustrating a relationship between some components of the deposition apparatus illustrated in FIG. 1.

FIG. 3 is a block diagram illustrating a relationship between some components of the deposition apparatus illustrated in FIG. 1.

FIG. 4 is a table showing first spacing distances and second spacing distances measured by respective displacement sensors illustrated in FIG. 2, and displacement differences calculated therefrom.

FIG. 5A is a conceptual diagram illustrating a change in position of a second holder based on a displacement sensor illustrated in FIG. 2 at a displacement difference measurement operation.

FIG. 5B is a conceptual diagram illustrating adjustment in position of the second holder illustrated in FIG. 2 at a position adjustment operation.

FIG. 5C is a conceptual diagram illustrating a change in the position of the second holder illustrated in FIG. 2 at a deposition operation.

FIG. 6 is a table showing a modification of the first spacing distances and the second spacing distances shown in FIG. 4, and the displacement differences calculated therefrom.

FIG. 7A is a conceptual diagram illustrating a modification of FIG. 5A.

FIG. 7B is a conceptual diagram illustrating a modification of FIG. 5B.

FIG. 7C is a conceptual diagram illustrating a modification of FIG. 5C.

FIG. 8 is a plan view illustrating a modification of the displacement sensors illustrated in FIG. 2, along with other components.

FIG. 9 is a sectional view schematically illustrating some components illustrated in FIG. 8.

FIG. 10 is a table illustrating first spacing distances and second spacing distances measured by respective displacement sensors illustrated in FIG. 8, and displacement differences calculated therefrom.

FIG. 11A is a conceptual diagram illustrating a change in position of a second holder based on a displacement sensor illustrated in FIG. 8 at a displacement difference measurement operation.

FIG. 11B is a conceptual diagram illustrating adjustment in position of the second holder illustrated in FIG. 8 at a position adjustment operation.

FIG. 11C is a conceptual diagram illustrating a change in the position of the second holder illustrated in FIG. 8 at a deposition operation.

FIG. 12 is a table showing a modification of the first spacing distances and the second spacing distances shown in FIG. 10, and the displacement differences calculated therefrom.

FIG. 13A is a conceptual diagram illustrating a modification of FIG. 11A.

FIG. 13B is a conceptual diagram illustrating a modification of FIG. 11B.

FIG. 13C is a conceptual diagram illustrating a modification of FIG. 11C.

FIG. 14 is a flowchart showing a method of driving the deposition apparatus 100 illustrated in FIG. 1.

FIG. 15 is a flowchart showing further details of the operation S1107 of FIG. 14.

FIG. 16 is a block diagram of an electronic device according to an embodiment.

FIG. 17 shows schematic views of various embodiments of an electronic device.

### DETAILED DESCRIPTION

Hereinafter, aspects of some embodiments of the present disclosure will be described in more detail with reference to the attached drawings. In the following description, only parts required for understanding of operations in accordance with the present disclosure will be described, and explanation of the other parts will be omitted not to make the gist of the present disclosure unclear. Accordingly, the present disclosure is not limited to the embodiments set forth herein but may be embodied in other types. Rather, these embodiments are provided so that the present disclosure will be thorough and complete, and will fully convey the technical spirit of the disclosure to those skilled in the art.

It will be understood that when an element is referred to as being “coupled” or “connected” to another element, an element can be directly coupled or connected to the other element or intervening elements may be present therebetween. The terminology used herein is for the purpose of describing particular embodiments only and is not intended to be limiting. For example, the singular forms are intended to include the plural forms as well, unless the context clearly indicates otherwise. In addition, when an element is referred to as “comprising” or “including” a component, it does not preclude another component but may further include the other component unless the context clearly indicates otherwise. “at least one of X, Y, or Z” and “at least one selected from the group consisting of X, Y, and Z” may be construed as X only, Y only, Z only, or any combination of two or more of X, Y, and Z (for instance, XYZ, XYY, YZ, and ZZ). As used herein, the term “and/or” can include any and all combinations of one or more of the associated listed items.

Here, the terms “first,” “second,” etc. may be used herein to describe various types of elements, and may be used to distinguish theses elements from other elements. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element or feature's relationship to another element(s) or feature(s), as illustrated in the drawings. Spatially relative descriptors are intended to encompass different orientations of an apparatus in use, operation, and/or manufacture in addition to the orientation depicted in the drawings. For example, if the device in the drawings is turned upside down, elements described as “below” or “beneath” other elements or features would then be oriented “above” the other elements or features. Thus, the term “below” can encompass both an orientation of above and below. Furthermore, the device may be otherwise oriented (e.g., rotated 90 degrees or at other orientations), and, as such, the spatially relative descriptors used herein interpreted accordingly.

Various embodiments will be described with reference to diagrams illustrating idealized embodiments. As such, variations from the shapes of the illustrations as a result, for example, of manufacturing techniques and/or tolerances, are to be expected. Therefore, embodiments disclosed herein should not be construed as limited to the particular illustrated shapes of regions, but are to include deviations in shapes that result from, for instance, manufacturing. As such, the shapes illustrated in the drawings may not illustrate the actual shapes of regions of a device, and, as such, are not intended to be limiting.

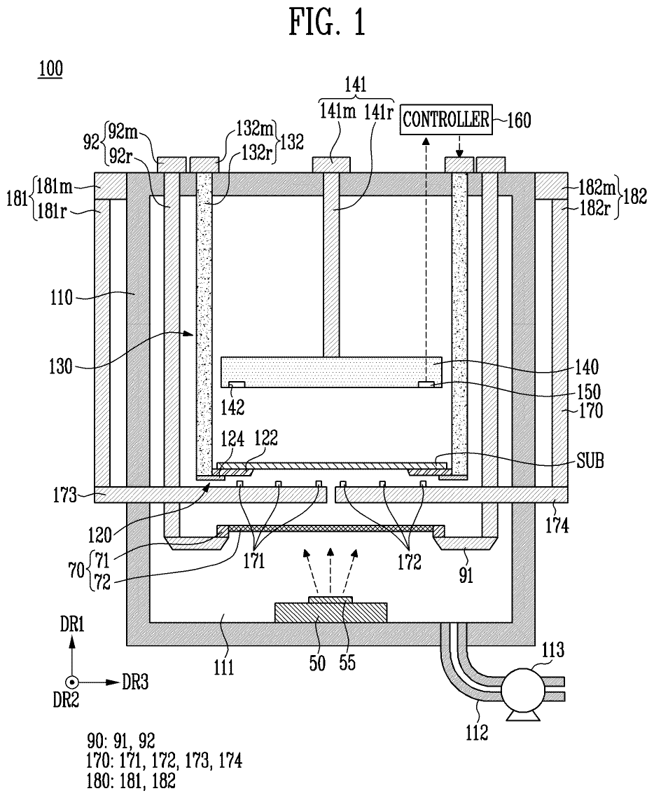

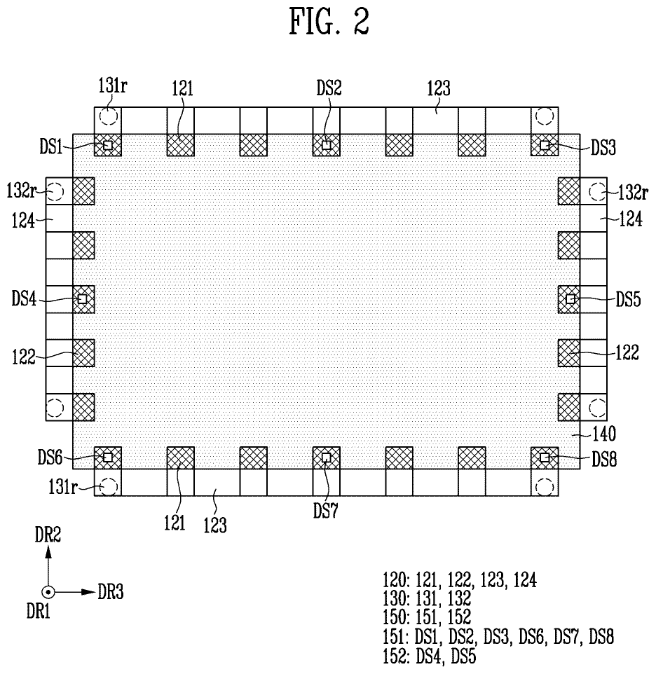

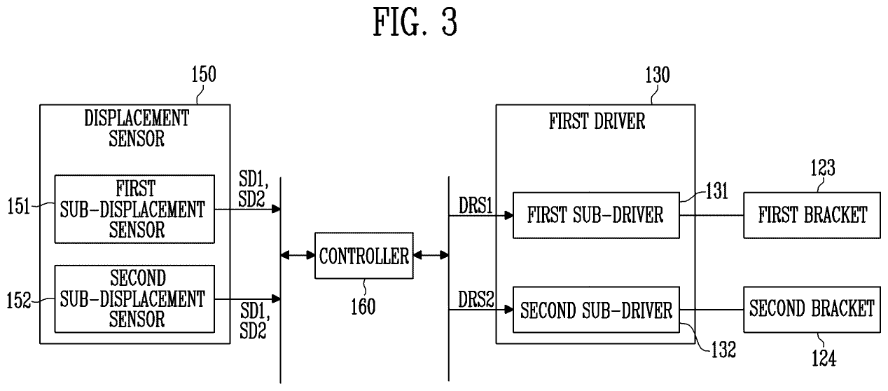

FIG. 1 is a conceptual diagram schematically illustrating aspects of a deposition apparatus 100 according to some embodiments. FIG. 2 is a plan view illustrating a relationship between some components of the deposition apparatus 100 illustrated in FIG. 1. FIG. 3 is a block diagram illustrating a relationship between some components of the deposition apparatus 100 illustrated in FIG. 1.

Hereinafter, a direction intersecting with a plane defined by second and third directions DR2 and DR3 may be defined as a first direction DR1. The first direction DR1 may intersect perpendicularly (or substantially perpendicularly) with the plane defined by the second and third directions DR2 and DR3. In the present specification, the term “on the plane”, “in a plan view”, or the like may refer to the perspective of viewing the plane defined by the second and third directions DR2 and DR3 from the first direction DR1.

Referring to FIG. 1, the deposition apparatus 100 may include a chamber 110, a substrate support 120, a first driver 130, an electrostatic chuck 140, a displacement sensor 150, and a controller 160.

The chamber 110 may include an internal space 111 that can be set to either atmospheric or vacuum conditions. A deposition process may be performed in the internal space 111 of the chamber 110.

The chamber 110 may include a suction pipe 112 and a vacuum pump 113. The suction pipe 112 may be a passage to discharge air from the internal space 111 out of the chamber 110 or introduce external air into the internal space 111. The vacuum pump 113 may be installed on the suction pipe 112 and provide driving force to discharge air from the internal space 111 to the outside. In other words, the vacuum pump 113 may regulate the pressure in the internal space 1110 according to the operation thereof. For example, the vacuum pump 113 may form the internal space 111 to either atmospheric or vacuum conditions.

A deposition source 50, a mask assembly 70, a mask support 90, the substrate support 120, the electrostatic chuck 140, and the displacement sensor 150 may be located in the internal space 111 of the chamber 110.

The deposition source 50 may be located in the internal space 111 of the chamber 110. The deposition source 50 may store material to be deposited onto the substrate SUB. The deposition source 50 may evaporate, vaporize, or sublimate at least one deposition material among organic material, inorganic material, and conductive material toward the substrate SUB. Deposition material evaporated from the deposition source 50 may pass through at least one opening formed in the mask assembly 70 and be deposited onto a deposition area of the substrate SUB. For example, the deposition source 50 may deposit the deposition material onto the deposition area of the substrate SUB by heating the deposition material to a high temperature to evaporate the deposition material. To this end, the deposition source 50 may include a heater configured to heat the deposition material.

According to some embodiments, the deposition apparatus 100 may further include a transfer unit configured to move the deposition source 50 in a horizontal direction (e.g., the second direction DR2 or the third direction DR3).

The deposition source 50 may include at least one nozzle 55 configured to guide a direction in which deposition material evaporated, vaporized, or sublimated from the deposition source 50 is sprayed toward the substrate SUB. In other words, the nozzle 55 may be connected to the deposition source 50 and configured to guide the deposition material evaporated, vaporized, or sublimated in the deposition source 50 toward the outside of the deposition source 50 (i.e., into the internal space 111 of the chamber 110). In the case where a plurality of nozzles 55 are formed in the deposition source 50, the nozzles 55 may be arranged in a dot nozzle form, spaced apart from each other at certain intervals. According to some embodiments, the nozzle 55 may also be provided in a line nozzle form, configured to spray the deposition material onto a certain area of the substrate SUB.

The mask assembly 70 may be located above the deposition source 50. The mask assembly 70 may include a mask frame 71 and a deposition mask 72.

The mask frame 71 may support the deposition mask 72. The mask frame 71 may have an opening allowing the deposition material to pass therethrough, and may include a plurality of frames enclosing the opening. The mask frame 71 may have a rectangular frame shape, but embodiments according to the present disclosure are not limited thereto. The mask frame 71 may have a shape corresponding to that of the deposition mask 72 to be supported by the mask frame 71.

The deposition mask 72 may be located on the mask frame 71. For example, the deposition mask 72 may be coupled and fixed to the mask frame 71. According to some embodiments, one deposition mask 72 may be located on the mask frame 71, but in some cases, a plurality of deposition masks may be located thereon. For example, in the case where a plurality of deposition masks are located on the mask frame 71, the deposition masks may be arranged in one direction (e.g., the second direction DR2 or the third direction DR3), thus closing at least a portion of the opening defined in the mask frame. Hereinafter, for the sake of convenience in explanation, an example will be primarily described, in which one deposition mask 72 is located on the mask frame 71 to close at least a portion of the opening of the mask frame 71.

The deposition mask 72 may be a fine metal mask (FMM) used to deposit R, G, and B pixels. In this case, the deposition mask 72 may be formed of materials with relatively low thermal expansion coefficients. For example, the deposition mask 72 may be formed of stainless steel, invar, nickel (Ni), cobalt (Co), a nickel alloy, a nickel-cobalt alloy. Consequently, a phenomenon of thermal deformation of the deposition mask 72 during a process of fabricating the deposition mask 72 or a process of depositing the deposition material on the substrate SUB using the deposition mask 72 may be mitigated.

The deposition mask 72 may include at least one opening. In the case where the deposition material is to be deposited in the overall area on the substrate SUB, the deposition mask 72 may include one opening. Alternatively, in the case where the deposition material is to be deposited in a plurality of areas separated from each other on the substrate SUB, the deposition mask 72 may include a plurality of openings. The openings may be formed in a pattern in which regular shapes are repeated, or may be formed in a pattern with different shapes for the respective areas.

The mask support 90 may support the mask assembly 70, or may provide driving force for moving the mask assembly 70 in the internal space 111 of the chamber 110.

The mask support 90 may include a mask holder 91 and a mask holder driver 92.

The mask holder 91 may support and fix the mask frame 71. The mask holder driver 92 may include a mask holder driving body 92m and a mask holder driving rod 92r.

The mask holder driving body 92m may transfer the mask holder 91 through the mask holder driving rod 92r in the first direction DR1 and a direction opposite to the first direction DR1. Furthermore, the mask holder driving body 92m may rotate the mask holder 91 within a certain angular range through the mask holder driving rod 92r, and may linearly move the mask holder 91 within a certain distance range in various directions. The mask holder driving body 92m may be located outside the chamber 110, and may include any one of a cylinder and a motor. For example, in the case where the mask holder driving body 92m includes a cylinder, the mask holder driving rod 92r may be a piston. According to some embodiments, in the case where the mask holder driving body 92m includes a motor, the mask holder driving rod 92r may be implemented as a ball screw shaft capable of moving upward and downward according to rotation of the motor. However, embodiments are not limited to the aforementioned examples, and the mask holder driver 92 may include various devices capable of moving the mask holder 91.

The mask holder driver 92 may raise and/or lower the mask holder 91 in the first direction DR1 and the direction opposite thereto, or may linearly move or rotate the mask holder 91 on the plane defined in the second direction DR2 and the third direction DR3. Hence, the mask assembly 70 located on the mask holder 91 may also be raised and/or lowered in the internal space 111, or be linearly moved or rotated on the plane defined in the second direction DR2 and the third direction DR3.

The substrate support 120 may be located in the internal space 111 of the chamber 110, and may support the substrate SUB. Furthermore, the substrate support 120 may be connected to a first driver 130, which will be described later, so that the substrate SUB may be moved upward, downward, leftward, and rightward or rotated by the substrate support 120 that moves according to the operation of the first driver 130.

The substrate SUB may be a mother substrate onto which the deposition material is deposited. The deposition material sprayed from the nozzle 55 and passing through the opening of the deposition mask 72 may be deposited on the substrate SUB. As such, an area of the substrate SUB that corresponds to the opening of the deposition mask 72 may be defined as the deposition area of the substrate SUB. Furthermore, another area of the substrate SUB that is covered with the deposition mask 72 may be defined as a non-deposition area of the substrate SUB. The substrate SUB may be made of glass, but is not limited thereto. The substrate SUB may include a flexible or elastic material, and may also include, for example, plastic or a metal material such as stainless steel (SS), or titanium (Ti).

Referring to FIGS. 1 and 2 together, the substrate support 120 may include a first holder 121, a second holder 122, a first bracket 123, and a second bracket 124.

The first holder 121 may support a first area of the substrate SUB. Here, the first area may refer to long sides of the substrate SUB. The first holder 121 may comprise a plurality of first holders 121 spaced apart from each other at regular intervals to uniformly support the first area of the substrate SUB. For example, as illustrated in FIG. 2, the first holder 121 may be provided as seven first holders 121 configured to support one of the long sides of the substrate SUB (e.g., an upper long side based on the second direction DR2), and seven first holders 121 configured to support a remaining one of the long sides of the substrate SUB (e.g., a lower long side based on the second direction DR2). However, the number of first holders 121 illustrated in FIG. 2 is merely for the sake of convenience in explanation, and the number of first holders 121 is not limited thereto. The first holders 121 may be provided in a number suitable for stably supporting the substrate SUB depending on the size of the substrate SUB. For instance, if arranging one first holder 121 on each of the long sides of the substrate SUB is sufficient to stably support the substrate SUB, it is possible that one first holder 121 is provided on each of the long sides of the substrate SUB.

The second holder 122 may support a second area of the substrate SUB. Here, the second area may be an area separate from the first area of the substrate SUB, and may refer to short sides of the substrate SUB. The second holder 122 may comprise a plurality of second holders 121 spaced apart from each other at regular intervals to uniformly support the second area of the substrate SUB. For example, as illustrated in FIG. 2, the second holder 122 may be provided as five second holders 122 configured to support one of the short sides of the substrate SUB (e.g., a left short side based on the third direction DR3), and five second holders 122 configured to support a remaining one of the short sides of the substrate SUB (e.g., a right short side based on the third direction DR3). However, the number of second holders 122 illustrated in FIG. 2 is not limited to the aforementioned example, in the same manner as that of the first holders 121. The description of the number of second holders 122 is the same as that of the first holders 121; therefore, redundant explanation thereof will be omitted.

The first bracket 123 may support a plurality of first holders 121. In other words, the first holders 121 may be located on the first bracket 123. The first bracket 123 may be connected to the first driver 130, which will be described in more detail later, and may thus be moved by driving force provided from the first driver 130. Here, the first holders 121 may be moved together by movement of the first bracket 123.

The second bracket 124 may support a plurality of second holders 122. In other words, the second holders 122 may be located on the second bracket 124. The second bracket 124 may be connected to the first driver 130, which will be described in more detail below, and may thus be moved by driving force provided from the first driver 130. Here, the second holders 122 may be moved together by movement of the second bracket 124.

The first driver 130 may be configured to reciprocate the substrate support 120 in the first direction DR1 and the direction opposite to the first direction DR1 (i.e., the up and down direction based on FIG. 1). The first driver 130 may include a first sub-driver 131 and a second sub-driver 132.

The first sub-driver 131 may include a first sub-driving body 131m and a first sub-driving rod 131r. In FIGS. 1 and 2, for the sake of convenience in explanation, the first sub-driving rod 131r is illustrated, but the first sub-driving body 131m is omitted. The first sub-driving body 131m may perform the same (or substantially the same) function as a second sub-driving body 132m shown in FIG. 1, except that the first sub-driving body 131m is connected to the first sub-driving rod 131r, as will be described later.

According to some embodiments, the first sub-driving body 131m may transfer the substrate support 120 through the first sub-driving rod 131r in the first direction DR1 and the direction opposite to the first direction DR1. Furthermore, the first sub-driving body 131m may rotate the substrate support 120 within a certain angular range through the first sub-driving rod 131r, and may linearly move the substrate support 120 within a certain distance range in various directions. The first sub-driving body 131m may be located outside the chamber 110, and may include any one of a cylinder and a motor. For example, in the case where the first sub-driving body 131m includes a cylinder, the first sub-driving rod 131r may be a piston. According to some embodiments, in the case where the first sub-driving body 131m includes a motor, the first sub-driving rod 130r may be implemented as a ball screw shaft capable of moving upward and downward according to rotation of the motor. However, embodiments are not limited to the aforementioned examples, and the first sub-driver 131 may include various devices capable of moving the substrate support 120.

The first sub-driver 131 may be connected to the first bracket 123. The first sub-driver 131 may transmit driving force to the first bracket 123, thus enabling the first bracket 123 to reciprocate in the first direction DR1 and the direction opposite to the first direction DR1. In other words, the first sub-driver 131 may change positions of the first holders 121 located on the first bracket 123.

The second sub-driver 132 may include a second sub-driving body 132m and a second sub-driving rod 132r.

The second sub-driving body 132m may transfer the substrate support 120 through the second sub-driving rod 132r in the first direction DR1 and the direction opposite to the first direction DR1. Furthermore, the second sub-driving body 132m may rotate the substrate support 120 within a certain angular range through the second sub-driving rod 132r, and may linearly move the substrate support 120 within a certain distance range in various directions. The second sub-driving body 132m may be located outside the chamber 110, and may include any one of a cylinder and a motor. For example, in the case where the second sub-driving body 132m includes a cylinder, the second sub-driving rod 132r may be a piston. According to some embodiments, in the case where the second sub-driving body 132m includes a motor, the second sub-driving rod 132r may be implemented as a ball screw shaft capable of moving upward and downward according to rotation of the motor. However, embodiments are not limited to the aforementioned examples, and the second sub-driver 132 may include various devices capable of moving the substrate support 120.

The second sub-driver 132 may be connected to the second bracket 124. The second sub-driver 132 may transmit driving force to the second bracket 124, thus enabling the second bracket 124 to reciprocate in the first direction DR1 and the direction opposite to the first direction DR1. In other words, the second sub-driver 132 may change positions of the second holders 122 located on the second bracket 124.

The electrostatic chuck 140 may be located in the internal space 111 of the chamber 110 at a position spaced apart from the substrate support 120 in the first direction DR1.

According to some embodiments, the electrostatic chuck 140 may chuck or dechuck the substrate SUB during a deposition process by generating electrostatic force through electrostatic induction. For example, the electrostatic chuck 140 may repeatedly perform operations of chucking the substrate SUB to allow an operation of processing the substrate SUB to be performed, and dechucking the substrate SUB to allow a subsequent operation to be performed after the deposition material is deposited on the substrate SUB. As such, as the substrate SUB is brought into close contact with the deposition mask 72 by electrostatic force generated from the electrostatic chuck 140, the substrate SUB may be secured in place and aligned at a desired position during the deposition process.

According to some embodiments, the deposition apparatus 100 may further include a power supply provided to supply power to the electrostatic chuck 140. As a certain voltage is applied from the power supply to electrodes provided in the electrostatic chuck, electrostatic force may be generated. Therefore, the substrate SUB and the deposition mask 72 may be brought into close contact with each other by the electrostatic force. For example, the electrostatic force generated from the electrostatic chuck 140 may attract the substrate SUB and the deposition mask 72 in the first direction DR1 toward the electrostatic chuck 140. For example, attractive force may be generated between the electrostatic chuck 140 and the substrate SUB and between the electrostatic chuck 140 and the deposition mask 72. Consequently, the substrate SUB and the deposition mask 72 can be attracted in the first direction DR1 by the attractive force. As a result, a phenomenon in which the substrate SUB and the deposition mask 72 sag in a direction opposite to the first direction DR1 due to the gravity may be prevented or relatively reduced.

The electrostatic chuck 140 may be connected to an electrostatic chuck driver 141 configured to provide driving force for raising and/or lowering the electrostatic shuck 140 in the first direction DR1 and the direction opposite thereto. To this end, the electrostatic driver 141 may include an electrostatic driving body 141m and an electrostatic driving rod 141r.

The electrostatic chuck driving body 141m may transfer the electrostatic chuck 140 through the electrostatic chuck driving rod 141r in the first direction DR1 and the direction opposite to the first direction DR1. Furthermore, the electrostatic chuck driving body 141m may rotate the electrostatic chuck 140 within a certain angular range through the electrostatic driving rod 141r, and may linearly move the electrostatic chuck 140 within a certain distance range in various directions. The electrostatic chuck driving body 141m may be located outside the chamber 110, and may include any one of a cylinder and a motor. For example, in the case where the electrostatic chuck driving body 141m includes a cylinder, the electrostatic chuck driving rod 141r may be a piston. According to some embodiments, in the case where the electrostatic chuck driving body 141m includes a motor, the electrostatic chuck driving rod 141r may be implemented as a ball screw shaft capable of moving upward and downward according to rotation of the motor. However, the aforementioned example is merely for illustrative, and the electrostatic chuck driver 141 may include various devices capable of moving the electrostatic chuck 140.

Referring to FIGS. 1 to 3 together, the displacement sensor 150 may be installed in the electrostatic chuck 140, and measure a first spacing distance SD1 from the substrate support 120 under atmospheric conditions and measure a second spacing distance SD2 from the substrate support 120 under vacuum conditions. The displacement sensor 150 may be located in a depression 142 formed in one surface of the electrostatic chuck 140 that faces the substrate support 120.

The displacement sensor 150 may include any type of linear displacement sensor. In other words, the displacement sensor 150 may be a non-contact displacement sensor, and may be any one selected from the group consisting of an eddy current displacement sensor, a magnetic displacement sensor, an optical displacement sensor, and an electromagnetic displacement sensor. Here, the types of displacement sensors listed above are merely illustrative, and the scope of the embodiments is not limited to these types of displacement sensors.

The displacement sensor 150 may include a first sub-displacement sensor 151 and a second sub-displacement sensor 152 that are respectively located in different areas.

The first sub-displacement sensor 151 may overlap at least one of the first holders 121, in a plan view. According to some embodiments, the first sub-displacement sensor 151 may be provided as a plurality of first sub-displacement sensors DS1 to DS3 and DS6 to DS8 that overlap the long sides of the substrate SUB, in a plan view.

The second sub-displacement sensor 152 may overlap at least one of the second holders 122, in a plan view. Furthermore, the second sub-displacement sensor 152 may be provided as a plurality of second sub-displacement sensors DS4 and DS5 that overlap the short sides of the substrate SUB, in a plan view. As such, in the case where multiple displacement sensors 150 are provided, a change in the position of the substrate SUB may be more accurately recognized compared to the case where a single displacement sensor 150 is provided.

Here, the first spacing distance SD1 may refer to a distance between any one displacement sensor 150 and the substrate support 120 that overlaps the corresponding displacement sensor 150 in a plan view, under conditions where the internal space 111 of the chamber 110 is in an atmospheric environment. In other words, under conditions where the internal space 111 of the chamber 110 is in the atmospheric environment, the first spacing distance SD1 may include a distance between any one first sub-displacement sensor 151 and the first holder 121 that overlaps the corresponding first sub-displacement sensor 151 in a plan view, and a distance between any one second sub-displacement sensor 152 and the second holder 122 that overlaps the corresponding second sub-displacement sensor 152 in a plan view.

As such, because the displacement sensor 150 may include the multiple first sub-displacement sensors 151 and the multiple second sub-displacement sensors 152, the first spacing distance SD1 may include a plurality of first spacing distances SD1 that are respectively measured by the first sub-displacement sensors 151 and the second sub-displacement sensors 152 under conditions in which the internal space 111 of the chamber 110 is in the atmospheric environment. The first spacing distances SD1 may be measured as the same or different values depending on the positions of the respective first and second sub-displacement sensors 151 and 152.

The second spacing distance SD2 may refer to a distance between any one displacement sensor 150 and the second holder 122 that overlaps the corresponding displacement sensor 150 in a plan view, under conditions where the internal space 111 of the chamber 110 is in a vacuum environment. In other words, under conditions where the internal space 111 of the chamber 110 is in the atmospheric environment, the second spacing distance SD2 may include a distance between any one first sub-displacement sensor 151 and the first holder 121 that overlaps the corresponding first sub-displacement sensor 151 in a plan view, and a distance between any one second sub-displacement sensor 152 and the second holder 122 that overlaps the corresponding second sub-displacement sensor 152 in a plan view.

As such, because the displacement sensor 150 may include the multiple first sub-displacement sensors 151 and the multiple second sub-displacement sensors 152, the second spacing distance SD2 may include a plurality of second spacing distances SD2 that are respectively measured by the first sub-displacement sensors 151 and the second sub-displacement sensors 152 under conditions in which the internal space 111 of the chamber 110 is in the vacuum environment. The second spacing distances SD2 may be measured as the same or different values depending on the positions of the respective first and second sub-displacement sensors 151 and 152.

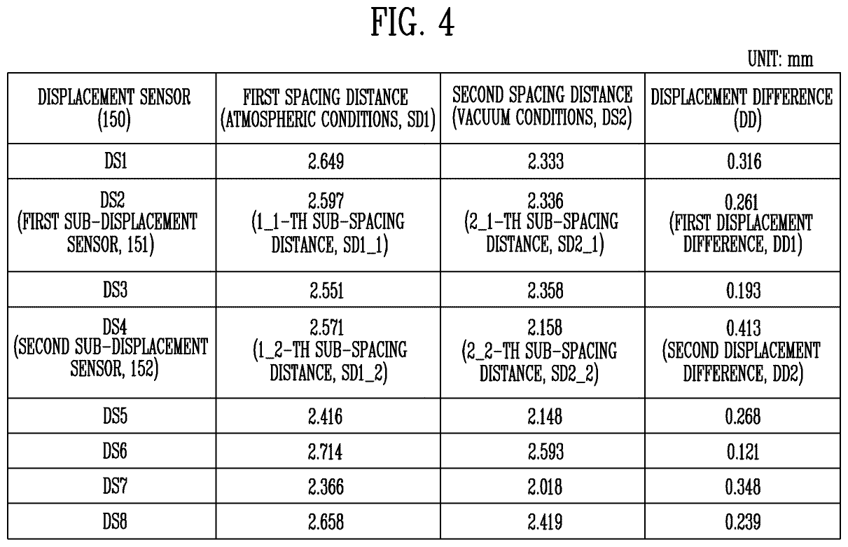

The controller 160 may adjust the position of the substrate support 120 based on a displacement difference (refer to DD in FIG. 4) between the first spacing distance SD1 and the second spacing distance SD2.

Referring to FIG. 3, the controller 160 may receive data of the first spacing distance SD1 and the second spacing distance SD2 from the displacement sensor 150.

As described above, the first spacing distance SD1 may be data about the first spacing distances SD1 that are respectively measured by the first sub-displacement sensors 151 and the second sub-displacement sensors 152 that are located at different positions, under conditions in which the internal space 111 of the chamber 110 is in the atmospheric environment. Furthermore, the second spacing distance SD2 may be data about the second spacing distances SD2 that are respectively measured by the first sub-displacement sensors 151 and the second sub-displacement sensors 152 that are located at different positions, under conditions in which the internal space 111 of the chamber 110 is in the vacuum environment. In other words, the controller 160 may receive data about the first spacing distances SD1 and the second spacing distances SD2 that are measured by the respective first and second sub-displacement sensors 151 and 152.

The controller 160 may calculate a displacement difference DD and transmit a first driving signal DRS1 and a second driving signal DRS2 derived based on the displacement difference DD to the first sub-driver 131 and the second sub-driver 132, respectively.

The first sub-driver 131 may move the first bracket 123 in the first direction DR1 or the direction opposite to the first direction DR1 based on the first driving signal DRS1. Furthermore, the second sub-driver 132 may move the second bracket 124 in the first direction DR1 or the direction opposite to the first direction DR1 based on the second driving signal DRS2.

Here, a detailed mechanism of deriving the first driving signal DRS1 and the second driving signal DRS2 based on the displacement difference DD will be described in more detail below with reference to FIGS. 4 to 13.

The deposition apparatus 100 may further include a pressing component 170 configured to press a lower side of the substrate SUB, and a second driver 180 configured to reciprocate the pressing component 170 in the first direction DR1 and the direction opposite to the first direction DR1.

The pressing component 170 may include a plurality of first pusher pins

171 configured to press a portion of the substrate SUB, and a plurality of second pusher pins 172 configured to press another portion of the substrate SUB. Furthermore, the pressing component 170 may include a third bracket 173 on which the first pusher pins 171 are located, and a fourth bracket 174 on which the second pusher pins 172 are located.

The second driver 180 may be configured to reciprocate the pressing component 170 in the first direction DR1 and the direction opposite to the first direction DR1 (i.e., the up and down direction based on FIG. 1). The second driver 180 may include a third sub-driver 181 and a fourth sub-driver 182.

The third sub-driver 181 may include a third sub-driving body 181m and a third sub-driving rod 181r.

The third sub-driving body 181m may transfer the pressing component 170 through the third sub-driving rod 181r in the first direction DR1 and the direction opposite to the first direction DR1. Furthermore, the third sub-driving body 181m may rotate the pressing component 170 within a certain angular range through the third sub-driving rod 181r, and may linearly move the pressing component 170 within a certain distance range in various directions. The third sub-driving body 181m may be located outside the chamber 110, and may include any one of a cylinder and a motor. For example, in the case where the third sub-driving body 181m includes a cylinder, the third sub-driving rod 181r may be a piston. According to some embodiments, in the case where the third sub-driving body 181m includes a motor, the third sub-driving rod 181r may be implemented as a ball screw shaft capable of moving upward and downward according to rotation of the motor. However, embodiments are not limited to the aforementioned examples, and the third sub-driver 181 may include various devices capable of moving the pressing component 170.

The third sub-driver 181 may be connected to the third bracket 173. The third sub-driver 181 may transmit driving force to the third bracket 173, thus enabling the third bracket 173 to reciprocate in the first direction DR1 and the direction opposite to the first direction DR1. In other words, the third sub-driver 181 may change positions of the first pusher pins 171 connected to the third bracket 173.

The fourth sub-driver 182 may include a fourth sub-driving body 182m and a fourth sub-driving rod 182r.

The fourth sub-driving body 182m may transfer the pressing component 170 through the fourth sub-driving rod 182r in the first direction DR1 and the direction opposite to the first direction DR1. Furthermore, the fourth sub-driving body 182m may rotate the pressing component 170 within a certain angular range through the fourth sub-driving rod 182r, and may linearly move the pressing component 170 within a certain distance range in various directions. The fourth sub-driving body 182m may be located outside the chamber 110, and may include any one of a cylinder and a motor. For example, in the case where the fourth sub-driving body 182m includes a cylinder, the fourth sub-driving rod 182r may be a piston. According to some embodiments, in the case where the fourth sub-driving body 182m includes a motor, the fourth sub-driving rod 182r may be implemented as a ball screw shaft capable of moving upward and downward according to rotation of the motor. However, embodiments are not limited to the aforementioned examples, and the fourth sub-driver 182 may include various devices capable of moving the pressing component 170.

The fourth sub-driver 182 may be connected to the fourth bracket 174. The fourth sub-driver 182 may transmit driving force to the fourth bracket 174, thus enabling the fourth bracket 174 to reciprocate in the first direction DR1 and the direction opposite to the first direction DR1. In other words, the fourth sub-driver 182 may change positions of the fourth pusher pins 172 connected to the fourth bracket 174.

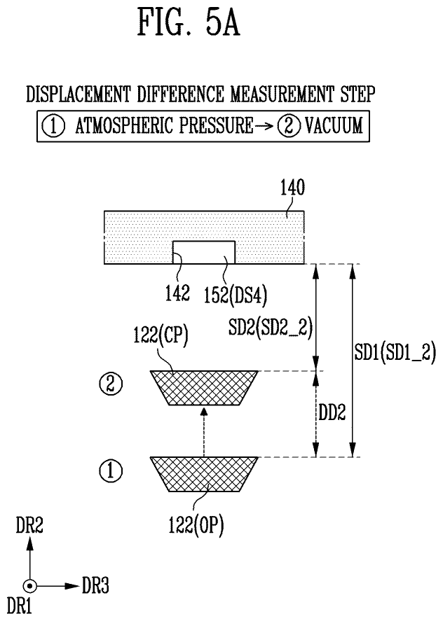

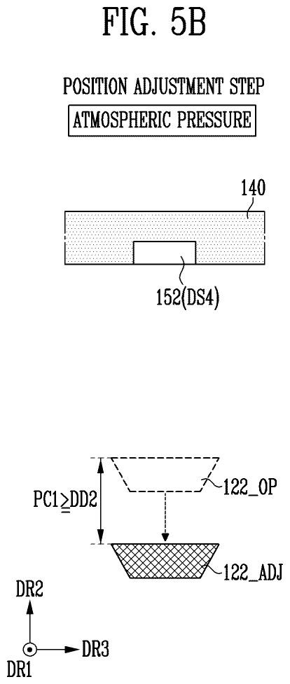

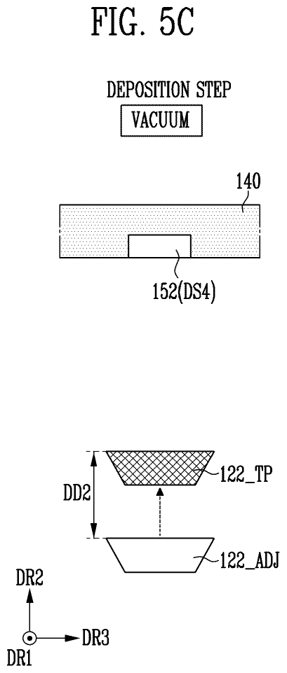

Hereinafter, a method of adjusting the position of the substrate support 120 based on the displacement difference DD will be described with reference to FIGS. 4 and 5.

FIG. 4 is a table illustrating first spacing distances SD1 and second spacing distances SD2 measured by the respective displacement sensors 150 illustrated in FIG. 2, and displacement differences calculated therefrom. FIG. 5A is a conceptual diagram illustrating a change in position of a second holder 122 based on a displacement sensor 150 illustrated in FIG. 2 at a displacement difference measurement operation. FIG. 5B is a conceptual diagram illustrating adjustment in the position of the second holder 122 illustrated in FIG. 2 at a position adjustment operation. FIG. 5C is a conceptual diagram illustrating a change in the position of the second holder 122 illustrated in FIG. 2 at a deposition operation.

Referring to FIG. 4, a total of eight displacement sensors 150 may be provided, as illustrated in FIG. 2. Among them, the six first sub-displacement sensors DS1 to DS3 and DS6 to DS8 may be arranged to overlap the long sides of the substrate SUB in a plan view, and the two second sub-displacement sensors DS4 and DS5 may be arranged to overlap the short sides of the substrate SUB in a plan view. However, the numbers of first sub-displacement sensors 151 and second sub-displacement sensors 152 shown in FIG. 4 are merely for illustrative purposes, the numbers of first sub-displacement sensors 151 and second sub-displacement sensors 152 are not limited thereto. For example, at least one first sub-displacement sensor 151 may be provided to overlap a long side of the substrate SUB in a plan view, and at least one second sub-displacement sensor 152 may be provided to overlap a short side of the substrate SUB in a plan view. Hereinafter, for the sake of convenience in explanation, the first spacing distance SD1, the second spacing distance SD2, and the displacement difference DD will be described, focusing on one first sub-displacement sensor DS2 and one second sub-displacement sensor DS4.

The first spacing distance SD1 may include a 1_1-th sub-spacing distance SD1_1 measured by the first sub-displacement sensor 151, and a 1_2-th sub-spacing distance SD1_2 measured by the second sub-displacement sensor 152.

The second spacing distance SD2 may include a 2_1-th sub-spacing distance SD2_1 measured by the first sub-displacement sensor 151, and a 2_2-th sub-spacing distance SD2_2 measured by the second sub-displacement sensor 152.

Measured by each of the displacement sensors 150, the second spacing distance SD2 may be less than the first spacing distance SD1.

For example, in the case where the internal space 111 of the chamber 110 is under atmospheric conditions, the 1_1-th sub-spacing distance SD1_1 measured by the first sub-displacement sensor DS2 is 2.597 mm. In this state, in the case where the internal space 111 of the chamber 110 is converted to vacuum conditions, the 2_1-th sub-spacing distance SD2_1 measured by the first sub-displacement sensor DS2 is 2.336 mm. In other words, in the case where the internal space 111 of the chamber 110 is converted from the atmospheric conditions to the vacuum conditions, compared to the first spacing distance SD1 measured by the first sub-displacement sensor DS2 the second spacing distance SD2 may be relatively reduced by a first displacement difference DD1. The foregoing indicates that in the case where the internal space 111 of the chamber 110 is converted from the atmospheric conditions to the vacuum conditions, the first holder 121 may move to a position closer to the first sub-displacement sensor DS2 by a first displacement difference DD1 of 0.261 mm compared to the position thereof when under the atmospheric conditions.

FIG. 5A illustrates a displacement difference measurement operation of measuring the first spacing distance SD1 between the second sub-displacement sensor DS4 and the second holder 122 in state \textcircled{1} in which the internal space 111 of the chamber 110 is under the atmospheric conditions, and measuring the second spacing distance SD2 between the second sub-displacement sensor DS4 and the second holder 122 in state \textcircled{2} in which the internal space 111 of the chamber 110 has been converted to the vacuum conditions.

Referring to FIGS. 4 and 5A together, in the case where the internal space 111 of the chamber 110 is under the atmospheric conditions, the 1_2-th sub-spacing distance SD1_2 measured by the second sub-displacement sensor DS4 is 2.571 mm. Here, in the case where the internal space 111 of the chamber 110 is under the atmospheric conditions, a position OP of the second holder 122 may be a position optimized (or targeted) to enable the substrate SUB to be stably seated on the electrostatic chuck 140 during a process of adsorbing the substrate SUB to the electrostatic chuck 140 to perform a deposition process. Given this, the position OP of the second holder 122 illustrated in FIG. 5A may refer to “original position” of the second holder 122 in the case where the internal space 111 of the chamber 110 is under the atmospheric conditions, and may also be referred to as “target position TP” to be described with reference to FIG. 5C.

In this state, in the case where the internal space 111 of the chamber 110 is converted to the vacuum conditions, the 2_2-th sub-spacing distance SD2_2 measured by the second sub-displacement sensor DS4 is 2.158 mm. In other words, in the case where the internal space 111 of the chamber 110 is converted from the atmospheric conditions to the vacuum conditions, the 2_2-th sub-spacing distance SD2_2 may be relatively reduced by a second displacement difference DD2 compared to the 1_2-th sub-spacing distance SD1_2. The foregoing indicates that in the case where the internal space 111 of the chamber 110 is converted from the atmospheric conditions to the vacuum conditions, the second holder 122 may move to a position CP closer to the second sub-displacement sensor DS4 by a second displacement difference DD2 of 0.413 mm compared to the position OP thereof when under the atmospheric conditions.

As such, each of the displacement sensors 150 may measure one first spacing distance SD1 and one second spacing distance SD2. A plurality of displacement differences DD may be derived by calculating differences between the respective first spacing distances SD1 and the corresponding second spacing distances SD2.

Among the displacement differences DD, the controller 160 may select one displacement difference DD having the largest value. For example, because the second displacement difference DD2 measured by the second sub-displacement sensor DS4 is 0.413 mm, which is larger than any one of the displacement differences DD measured by the other displacement sensors DS1 to DS3 and DS5 to DS8, the second displacement difference DD2 may be selected as a displacement difference DD that is a basis for adjusting the position of the substrate support 120 to be described later. As such, the displacement difference DD having the largest value selected by the controller 160 may be basic data of the first driving signal DRS1 and the second driving signal DRS2.

FIG. 5B illustrates a position adjustment operation of adjusting the position of the substrate support 120, based on the second displacement difference DD2 calculated and selected through the displacement difference measurement operation described above.

Referring to FIG. 5B, in the state where the internal space 111 of the chamber 110 is under the atmospheric conditions, the position of the second holder 122 may be adjusted from the original position OP by a first position variation PC1 in a direction away from the electrostatic chuck 140, in other words, in the direction opposite to the second direction DR2 (i.e., OP→ADJ).

As such, in the case where the second spacing distance SD2 is less than the first spacing distance SD1, the controller 160 may respectively transmit the first driving signal DRS1 and the second driving signal DRS2 to the first sub-driver 131 and the second sub-driver 132, based on data about a selected one displacement difference DD, and thus adjust the position of the substrate support 120 (i.e., including the positions of the first and second holders 121 and 122 and the first and second brackets 123 and 124, which are sub-elements of the substrate support 120) by the first position variation PC1 in a direction away from the electrostatic chuck 140.

Here, the first position variation PC1 may be equal to or greater than the second displacement difference DD2 that is calculated and selected at the displacement difference measurement operation. As a result, at a deposition operation to be described later with reference to FIG. 5C, the substrate SUB may be positioned farther from the electrostatic chuck 140 than the target position TP, thereby preventing or relatively reducing damage to or breaking of the substrate SUB due to excessive pressure during the adsorption operation of the substrate SUB and the electrostatic chuck 140.

FIG. 5C illustrates conversion of the internal space 111 of the chamber 110 from the atmospheric conditions to the vacuum conditions so as to enable the deposition apparatus 100 to perform a deposition process.

In the case where the internal space 111 of the chamber 110 is converted from the atmospheric conditions to the vacuum conditions, the second holder 122 may move in the second direction DR2, approaching the electrostatic chuck 140, by the distance moved at the displacement difference measurement operation (i.e., the second displacement difference DD2), and be located at the target position TP. As described above, the target position TP may be an optimized position of the second holder 122 to enable the substrate SUB to be stably seated on the electrostatic chuck 140. Consequently, during a process in which the substrate SUB is adsorbed to the electrostatic chuck 140, damage to or breaking of the substrate SUB may be prevented or relatively reduced.

If the position of the second holder 122 is not adjusted to the position ADJ away from the electrostatic chuck 140 through the aforementioned position adjustment operation, the second holder 122 may be located at the position CP closer to the electrostatic chuck 140 than the target position TP at the deposition operation. In this case, during a process in which the substrate SUB and the electrostatic chuck 140 approach each other, the substrate SUB and the electrostatic chuck 140 may already come into contact with each other before power is applied to the electrostatic chuck 140 to attract the substrate SUB using electrostatic force, resulting in unintended physical force being applied to the substrate SUB, thus causing the substrate SUB to be damaged or broken.

In this way, after the position variation (i.e., the displacement difference DD) of the second holder 122 due to a change in pressure conditions of the internal space 111 of the chamber 110 is measured at the displacement difference measurement operation, the position of the second holder 122 is adjusted at the position adjustment operation. Accordingly, a phenomenon in which unintended pressure applied to the substrate SUB before or after the substrate SUB is adsorbed to the electrostatic chuck 140 during the deposition process causes the substrate SUB to be damaged or broken may be mitigated.

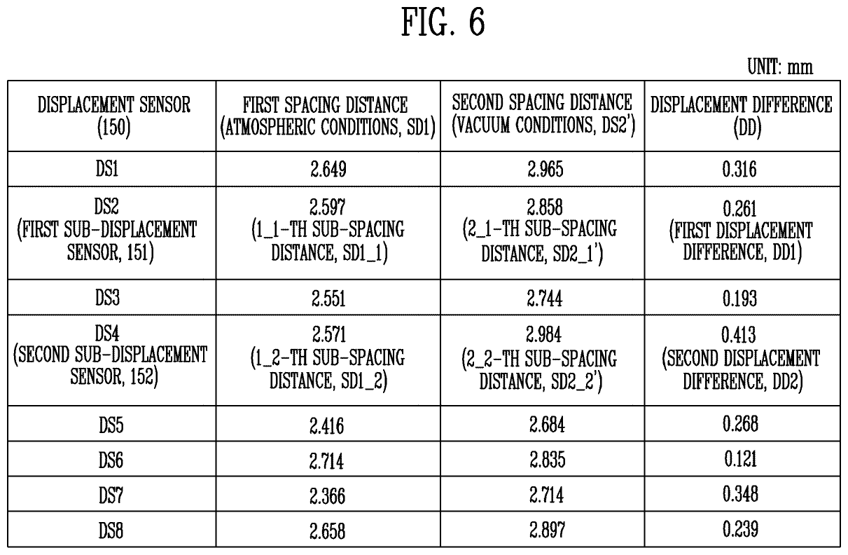

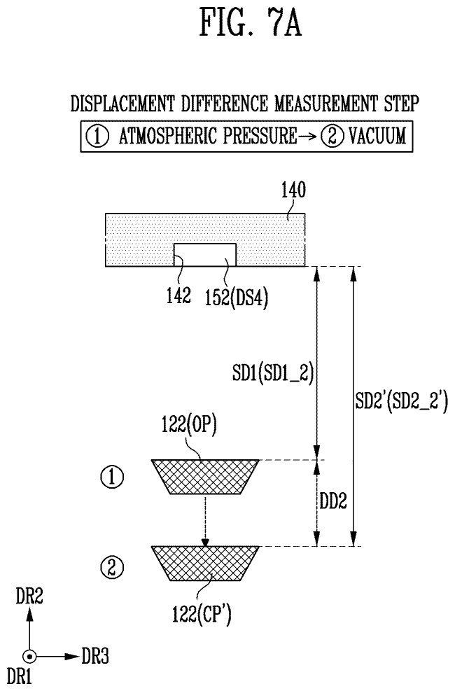

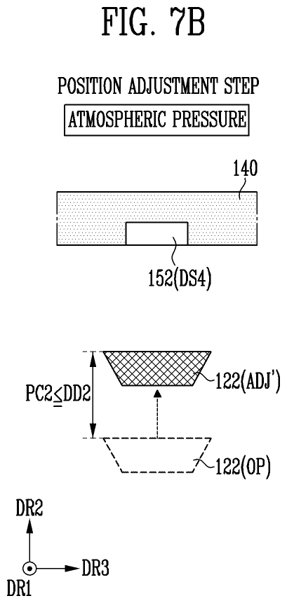

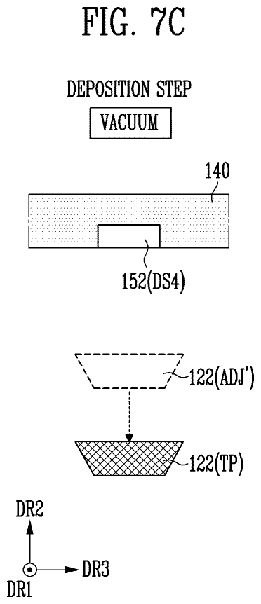

FIG. 6 is a table showing a modification of the first spacing distances, the second spacing distances shown in FIG. 4, and the displacement differences calculated therefrom. FIG. 7A is a conceptual diagram illustrating a modification of FIG. 5A. FIG. 7B is a conceptual diagram illustrating a modification of FIG. 5B. FIG. 7C is a conceptual diagram illustrating a modification of FIG. 5C.

Displacement sensors 150, a first spacing distance SD1, a second spacing distance SD2′, and a displacement difference DD that are shown in FIG. 6 may be formed in the same manner as the displacement sensors 150, the first spacing distance SD1, the second spacing distance SD2, and the displacement difference DD that are described with reference to FIG. 4. Hereinafter, redundant descriptions will be omitted.

Referring to FIG. 6, measured by each of the displacement sensors 150, the second spacing distance SD2′ may be greater than the first spacing distance SD1.

For example, in the case where the internal space 111 of the chamber 110 is under atmospheric conditions, the 1_1-th sub-spacing distance SD1_1 measured by the first sub-displacement sensor DS2 is 2.597 mm. In this state, in the case where the internal space 111 of the chamber 110 is converted to vacuum conditions, the 2_1-th sub-spacing distance SD2_1′ measured by the first sub-displacement sensor DS2 is 2.858 mm. In other words, in the case where the internal space 111 of the chamber 110 is converted from the atmospheric conditions to the vacuum conditions, compared to the first spacing distance SD1 measured by the first sub-displacement sensor DS2 the second spacing distance SD2′ may be increased by a first displacement difference DD1. The foregoing indicates that in the case where the internal space 111 of the chamber 110 is converted from the atmospheric conditions to the vacuum conditions, the first holder 121 may move in a direction away from the first sub-displacement sensor DS2 by a first displacement difference DD1 of 0.261 mm compared to the position thereof when under the atmospheric conditions.

FIG. 7A illustrates a displacement difference measurement operation of measuring the first spacing distance SD1 between the second sub-displacement sensor DS4 and the second holder 122 in state \textcircled{1} in which the internal space 111 of the chamber 110 is under the atmospheric conditions, and measuring the second spacing distance SD2′ between the second sub-displacement sensor DS4 and the second holder 122 in state \textcircled{2} in which the internal space 111 has been converted to the vacuum conditions.

Referring to FIGS. 6 and 7A together, in the case where the internal space 111 of the chamber 110 is under the atmospheric conditions, the 1_2-th sub-spacing distance SD1_2 measured by the second sub-displacement sensor DS4 is 2.571 mm. Here, the position OP of the second holder 122 may be a position optimized (or targeted) to enable the substrate SUB to be stably seated on the electrostatic chuck 140 during a process of adsorbing the substrate SUB to the electrostatic chuck 140 to perform a deposition operation. Given this, the position OP of the second holder 122 illustrated in FIG. 7A may refer to “original position” of the second holder 122 in the case where the internal space 111 of the chamber 110 is under the atmospheric conditions, and may also be referred to as “target position TP” to be described with reference to FIG. 7C.

In this state, in the case where the internal space 111 of the chamber 110 is converted to the vacuum conditions, a 2_2-th sub-spacing distance SD2_2′ measured by the second sub-displacement sensor DS4 is 2.984 mm. In other words, in the case where the internal space 111 of the chamber 110 is converted from the atmospheric conditions to the vacuum conditions, the 2_2-th sub-spacing distance SD2_2′ may be increased by a second displacement difference DD2 compared to the 1_2-th sub-spacing distance SD1_2. The foregoing indicates that in the case where the internal space 111 of the chamber 110 is converted from the atmospheric conditions to the vacuum conditions, the second holder 122 may move to a position CP′ more distant from the second sub-displacement sensor DS4 by a second displacement difference DD2 of 0.413 mm compared to the position OP thereof under the atmospheric conditions.

As such, each of the displacement sensors 150 may measure one first spacing distance SD1 and one second spacing distance SD2′. A plurality of displacement differences DD may be derived by calculating differences between the respective first spacing distances SD1 and the corresponding second spacing distances SD2′. Among the displacement differences DD, the controller 160 may select one displacement difference DD having the largest value. For example, because the second displacement difference DD2 measured by the second sub-displacement sensor DS4 is 0.413 mm, which is larger than any one of the displacement differences DD measured by the other displacement sensors DS1 to DS3 and DS5 to DS8, the second displacement difference DD2 may be selected as a displacement difference DD that is a basis for adjusting the position of the substrate support 120 to be described later.

FIG. 7B illustrates a position adjustment operation of adjusting the position of the substrate support 120, based on the second displacement difference DD2 calculated and selected through the displacement difference measurement operation described above.

Referring to FIG. 7B, in the state where the internal space 111 of the chamber 110 is under the atmospheric conditions, the position of the second holder 122 may be adjusted from the original position OP by a second position variation PC2 in a direction approaching the electrostatic chuck 140, in other words, in the second direction DR2 (i.e., OP→ADJ′).

As such, in the case where the second spacing distance SD2′ is greater than the first spacing distance SD1, the controller 160 may adjust the position of the substrate support 120 (i.e., including the positions of the first and second holders 121 and 122 and the first and second brackets 123 and 124, which are sub-elements of the substrate support 120) by the second position variation PC2 in a direction approaching the electrostatic chuck 140.

Here, the second position variation PC2 may be smaller than or equal to the second displacement difference DD2 that is calculated and selected at the displacement difference measurement operation. As a result, at a deposition operation to be described later with reference to FIG. 7C, the substrate SUB may be positioned closer to the electrostatic chuck 140 than the target position TP, thereby preventing or relatively reducing damage to or breaking of the substrate SUB due to excessive pressure during the adsorption operation of the substrate SUB and the electrostatic chuck 140.

FIG. 7C illustrates conversion of the conditions of the internal space 111 of the chamber 110 from the atmospheric conditions to the vacuum conditions so as to enable the deposition apparatus 100 to perform a deposition process.

In the case where the internal space 111 of the chamber 110 is converted from the atmospheric conditions to the vacuum conditions, the second holder 122 may move in the opposite direction to the second direction DR2, i.e., in a direction away from the electrostatic chuck 140, by the distance moved at the displacement difference measurement operation (i.e., the second displacement difference DD2), and be located at the target position TP. As described above, the target position TP may be an optimized position of the second holder 122 to enable the substrate SUB to be stably seated on the electrostatic chuck 140. Consequently, during a process in which the substrate SUB is adsorbed to the electrostatic chuck 140, damage to or breaking of the substrate SUB may be prevented or relatively reduced.

If the position of the second holder 122 is not adjusted to the position ADJ′ approaching the electrostatic chuck 140 through the aforementioned position adjustment operation, the second holder 122 may be located at a position CP′ more distant from the target position TP. In this case, during a process in which the substrate SUB and the electrostatic chuck 140 approach each other, even if power is applied to the electrostatic chuck 140, a minimum distance required for the substrate SUB to be adsorbed to the electrostatic chuck 140 may not be secured.

In this way, after the position variation (i.e., the displacement difference DD) of the second holder 122 due to a change in pressure conditions of the internal space 111 of the chamber 110 is measured at the displacement difference measurement operation, the position of the second holder 122 is adjusted at the position adjustment operation. Accordingly, the minimum distance required for the substrate SUB to be sufficiently adsorbed to the electrostatic chuck 140 during the deposition process may be secured.

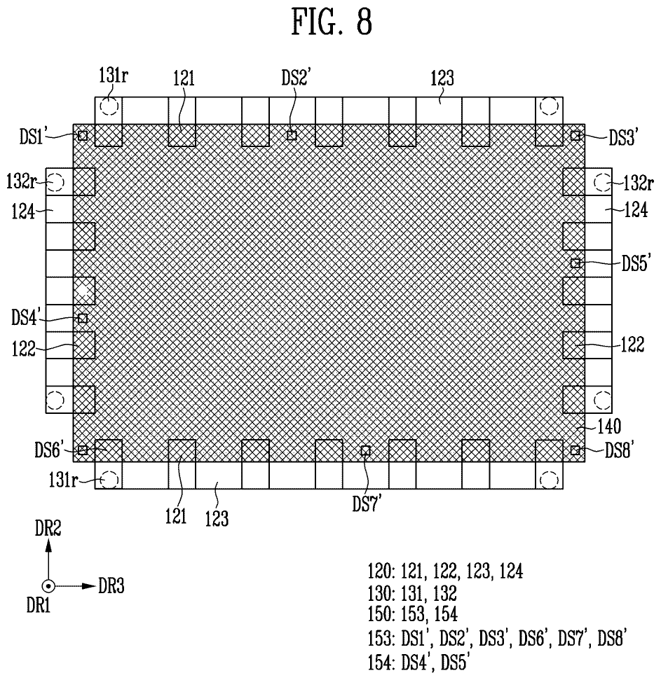

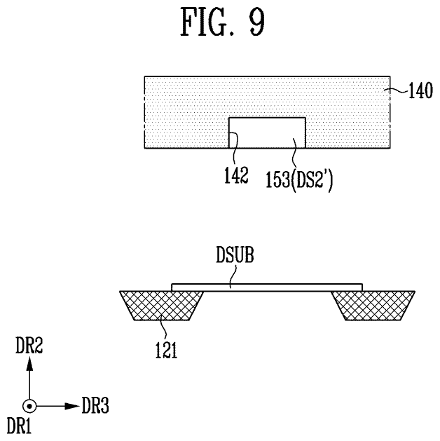

FIG. 8 is a plan view illustrating a modification of the displacement sensors illustrated in FIG. 2, along with other components. FIG. 9 is a sectional view schematically illustrating some components illustrated in FIG. 8.

A first holder 121, a second holder 122, a first bracket 123, a second bracket 124, a first sub-driver 131, and a second sub-driver 132 that are illustrated in FIG. 8 may be respectively configured in the same manner as the first holder 121, the second holder 122, the first bracket 123, the second bracket 124, the first sub-driver 131, and the second sub-driver 132 that are illustrated in FIG. 2. Hereinafter, redundant descriptions will be omitted.

Referring to FIG. 8, the displacement sensor 150 may include a third sub-displacement sensor 153 and a fourth sub-displacement sensor 154 that are respectively located in different areas.

The third sub-displacement sensor 153 may not overlap the first holders 121 in a plan view based on the first direction DR1. Furthermore, the third sub-displacement sensor 153 may be provided as a plurality of third sub-displacement sensors DS1′ to DS3′ and DS6′ to DS8′ that overlap the long sides of the substrate SUB based on the first direction DR1.

The fourth sub-displacement sensor 154 may not overlap the second holders 122 in a plan view based on the first direction DR1. Furthermore, the fourth sub-displacement sensor 154 may be provided as a plurality of fourth sub-displacement sensors DS4′ and DS5′ that overlap the short sides of the substrate SUB based on the first direction DR1.

As such, in the case where the multiple displacement sensors 150 are provided, a change in the position of the substrate SUB may be more accurately recognized compared to the case where a single displacement sensor 150 is provided. Consequently, even when the internal space 111 of the chamber 110 is converted from the atmospheric conditions to the vacuum conditions, the substrate SUB can be positioned at an intended position.

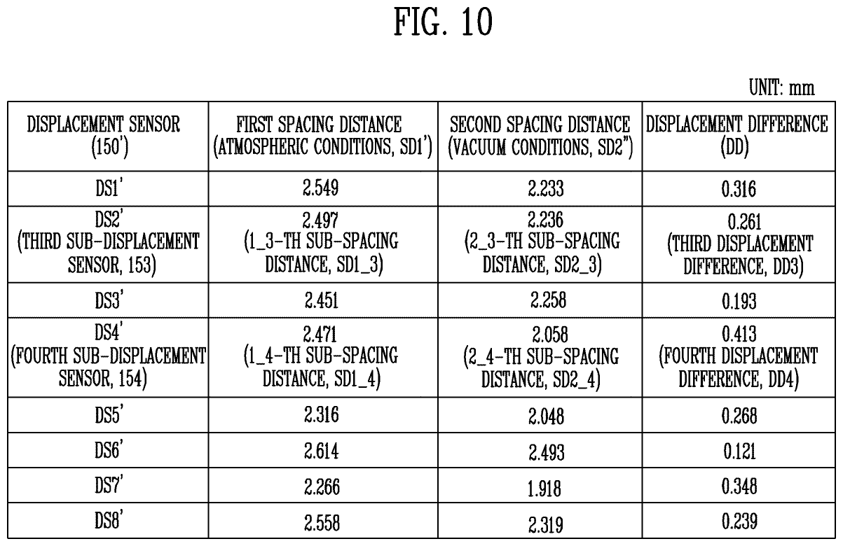

Referring to FIGS. 8 and 9 together, the first spacing distance (refer to SD1′ in FIG. 10) may refer to a shortest distance between any one of the displacement sensors 150 and a dummy substrate DSUB located on the substrate support 120 in a state in which the internal space 111 of the chamber 110 is in the atmospheric environment. In other words, in the state in which the internal space 111 of the chamber 110 is in the atmospheric environment, the first spacing distance SD1′ may refer to the shortest distance between any one of the third sub-displacement sensors 153 and one area of the dummy substrate DSUB located on the first holder 121, and the shortest distance between any one of the fourth sub-displacement sensors 154 and another area of the dummy substrate DSUB located on the second holder 122. Here, the term “shortest distance” may refer to the length of a shortest straight line among imaginary straight lines connecting any one of the displacement sensors 150 and the dummy substrate DSUB.

As such, because the displacement sensor 150 may include the multiple third sub-displacement sensors 153 and the multiple fourth sub-displacement sensors 154, the first spacing distance SD1′ may include a plurality of first spacing distances SD1′ that are respectively measured by the third sub-displacement sensors 153 and the fourth sub-displacement sensors 154 under conditions in which the internal space 111 of the chamber 110 is in the atmospheric pressure environment. The first spacing distances SD1′ may be measured as the same or different values depending on the locations of the respective third and fourth sub-displacement sensors 153 and 154.

The second spacing distance (refer to SD2″ in FIG. 10) may refer to a shortest distance between any one of the displacement sensors 150 and the dummy substrate DSUB located on the substrate support 120 in a state in which the internal space 111 of the chamber 110 is in the vacuum environment. In other words, in the state in which the internal space 111 of the chamber 110 is in the vacuum environment, the second spacing distance SD2″ may refer to the shortest distance between any one of the third sub-displacement sensors 153 and one area of the dummy substrate DSUB located on the second holder 122, and the shortest distance between any one of the fourth sub-displacement sensors 154 and another area of the dummy substrate DSUB located on the second holder 122.

As such, because the displacement sensor 150 may include the multiple third sub-displacement sensors 153 and the multiple fourth sub-displacement sensors 154, the second spacing distance SD2″ may include a plurality of second spacing distances SD2″ that are respectively measured by the third sub-displacement sensors 153 and the fourth sub-displacement sensors 154 under conditions in which the internal space 111 of the chamber 110 is in the vacuum environment. The second spacing distances SD2″ may be measured as the same or different values depending on the locations of the respective third and fourth sub-displacement sensors 153 and 154.

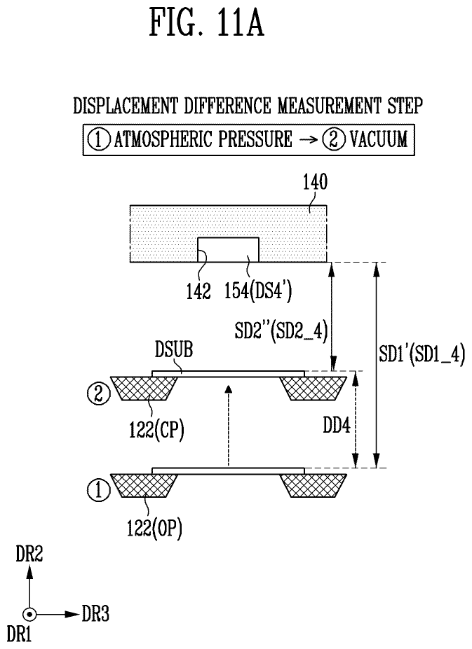

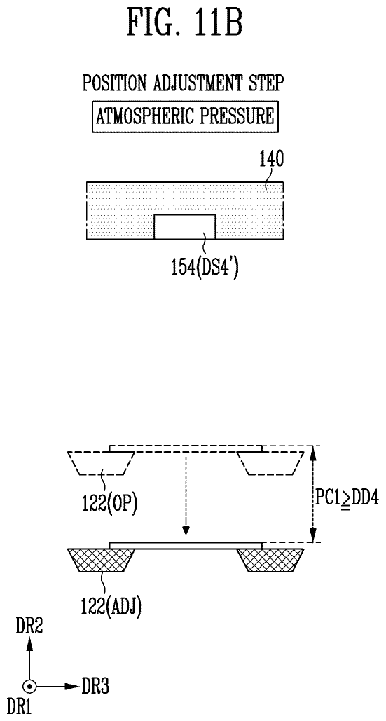

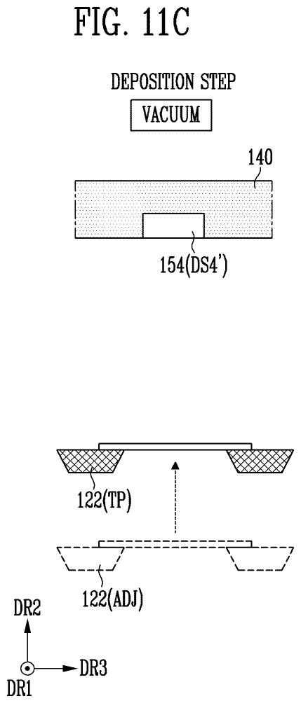

Hereinafter, a method of adjusting the location of the substrate support 120 based on the displacement difference DD will be described with reference to FIGS. 10 and 11.

FIG. 10 is a table illustrating first spacing distances SD1′ and second spacing distances SD2″ measured by respective displacement sensors illustrated in FIG. 8, and displacement differences calculated therefrom. FIG. 11A is a conceptual diagram illustrating a change in position of a second holder 122 based on a displacement sensor illustrated in FIG. 8 at a displacement difference measurement operation. FIG. 11B is a conceptual diagram illustrating adjustment in position of the second holder 122 illustrated in FIG. 8 at a position adjustment operation. FIG. 11C is a conceptual diagram illustrating a change in the position of the second holder 122 illustrated in FIG. 8 at a deposition operation.

Referring to FIG. 10, a total of eight displacement sensors 150′ may be provided, as illustrated in FIG. 8. Among them, six third sub-displacement sensors DS1′ to DS3′ and DS6′ to DS8′ may be arranged to overlap the long sides of the substrate SUB in a plan view, and two fourth sub-displacement sensors DS4′ and DS5′ may be arranged to overlap the short sides of the substrate SUB in a plan view. However, the numbers of third sub-displacement sensors 153 and fourth sub-displacement sensors 154 shown in FIG. 8 are merely for illustrative purposes, the numbers of third sub-displacement sensors 153 and fourth sub-displacement sensors 154 are not limited thereto. For example, at least one third sub-displacement sensor 153 may be provided to overlap a long side of the substrate SUB in a plan view, and at least one fourth sub-displacement sensor 154 may be provided to overlap a short side of the substrate SUB in a plan view. Hereinafter, for the sake of convenience in explanation, a first spacing distance SD1′, a second spacing distance SD2″, and a displacement difference DD will be described, focusing on one third sub-displacement sensor DS2′ and one fourth sub-displacement sensor DS4′.

The first spacing distance SD1′ may include a 1_3-th sub-spacing distance SD1_3 measured by the third sub-displacement sensor 153 and defined between the third sub-displacement sensor 153 and one area of the dummy substrate DSUB located on the first holder 121, and a 1_4-th sub-spacing distance SD1_4 measured by the fourth sub-displacement sensor 154 and defined between the fourth sub-displacement sensor 154 and another area of the dummy substrate DSUB located on the second holder 122.

The second spacing distance SD2″ may include a 2_3-th sub-spacing distance SD2_3 measured by the third sub-displacement sensor 153 and defined between the third sub-displacement sensor 153 and one area of the dummy substrate DSUB located on the second holder 122, and a 2_4-th sub-spacing distance SD2_4 measured by the fourth sub-displacement sensor 154 and defined between the fourth sub-displacement sensor 154 and another area of the dummy substrate DSUB located on the second holder 122.

Measured by each of the displacement sensors 150′, the second spacing distance SD2″ may be less than the first spacing distance SD1′.

For example, in the case where the internal space 111 of the chamber 110 is under atmospheric conditions, the 1_3-th sub-spacing distance SD1_3 measured by the third sub-displacement sensor DS2′ is 2.497 mm. In this state, in the case where the internal space 111 of the chamber 110 is converted to the vacuum conditions, the 2_3-th sub-spacing distance SD2_3 measured by the third sub-displacement sensor DS2′ is 2.236 mm. In other words, in the case where the internal space 111 of the chamber 110 is converted from the atmospheric conditions to the vacuum conditions, compared to the first spacing distance SD1′ measured by the third sub-displacement sensor DS2′ the second spacing distance SD2″ may be relatively reduced by a third displacement difference DD3. The foregoing indicates that in the case where the internal space 111 of the chamber 110 is converted from the atmospheric conditions to the vacuum conditions, the first holder 121 may move to a position closer to the third sub-displacement sensor DS2′ by a third displacement difference DD3 of 0.261 mm compared to the position thereof when under the atmospheric conditions.

FIG. 11A illustrates a displacement difference measurement operation of measuring the first spacing distance SD1′ between the fourth sub-displacement sensor DS4′ and the second holder 122 in state \textcircled{1} in which the internal space 111 of the chamber 110 is under the atmospheric conditions, and measuring the second spacing distance SD2″ between the fourth sub-displacement sensor DS4′ and the second holder 122 in state \textcircled{2} in which the internal space 111 of the chamber 110 has been converted to the vacuum conditions.

Referring to FIGS. 10 and 11A together, in the case where the internal space 111 of the chamber 110 is under the atmospheric conditions, the 1_4-th sub-spacing distance SD1_4 measured by the fourth sub-displacement sensor DS4′ is 2.471 mm. Here, in the case where the internal space 111 of the chamber 110 is under the atmospheric conditions, a position OP of the second holder 122 may be a position optimized (or targeted) to enable the substrate SUB to be stably seated on the electrostatic chuck 140 during a process of adsorbing the substrate SUB to the electrostatic chuck 140 to perform a deposition process. Given this, in the state in which the internal space 111 of the chamber 110 is under the atmospheric conditions, the position OP of the second holder 122 illustrated in FIG. 11A may refer to “original position” of the second holder 122, and may also be referred to as “target position TP” to be described with reference to FIG. 11C.

In this state, in the case where the internal space 111 of the chamber 110 is converted to the vacuum conditions, a 2_4-th sub-spacing distance SD2_4 measured by the second sub-displacement sensor DS4′ is 2.058 mm. In other words, in the case where the internal space 111 of the chamber 110 is converted from the atmospheric conditions to the vacuum conditions, the 2_4-th sub-spacing distance SD2_4 may be relatively reduced by a fourth displacement difference DD4 compared to the 1_4-th sub-spacing distance SD1_4. The foregoing indicates that in the case where the internal space 111 of the chamber 110 is converted from the atmospheric conditions to the vacuum conditions, the second holder 122 may move to a position CP closer to the fourth sub-displacement sensor DS4′ by a fourth displacement difference DD4 of 0.413 mm compared to the position OP thereof when under the atmospheric conditions.

As such, each of the displacement sensors 150 may measure one first spacing distance SD1′ and one second spacing distance SD2″. A plurality of displacement differences DD may be derived by calculating differences between the respective first spacing distances SD1′ and the corresponding second spacing distances SD2″. Among the displacement differences DD, the controller 160 may select one displacement difference DD having the largest value. For example, because the fourth displacement difference DD4 measured by the fourth sub-displacement sensor DS4′ is 0.413 mm, which is larger than any one of the displacement differences DD measured by the other displacement sensors DS1′ to DS3′ and DS5′ to DS8′, the fourth displacement difference DD4 may be selected as a displacement difference DD that is a basis for adjusting the position of the substrate support 120 to be described later.

FIG. 11B illustrates a position adjustment operation of adjusting the position of the substrate support 120, based on the fourth displacement difference DD4 calculated and selected through the displacement difference measurement operation described above.

Referring to FIG. 11B, in the state where the internal space 111 of the chamber 110 is under the atmospheric conditions, the position of the second holder 122 may be adjusted from the original position OP by a first position variation PC1 in a direction away from the electrostatic chuck 140, in other words, in the direction opposite to the second direction DR2 (i.e., OP→ADJ).

As such, in the case where the second spacing distance SD2″ is less than the first spacing distance SD1′, the controller 160 may adjust the position of the substrate support 120 (i.e., including the positions of the first and second holders 121 and 122 and the first and second brackets 123 and 124, which are sub-elements of the substrate support 120) by the first position variation PC1 in a direction away from the electrostatic chuck 140.

Here, the first position variation PC1 may be equal to or greater than the fourth displacement difference DD4 that is calculated and selected at the displacement difference measurement operation. As a result, at a deposition operation to be described later with reference to FIG. 11C, the substrate SUB may be positioned farther from the electrostatic chuck 140 than the target potion TP, thereby preventing the substrate SUB from being damaged or broken due to excessive pressure during the adsorption operation of the substrate SUB and the electrostatic chuck 140.

FIG. 11C illustrates conversion of the conditions of the internal space 111 of the chamber 110 from the atmospheric conditions to the vacuum conditions so as to enable the deposition apparatus 100 to perform a deposition process.

In the case where the internal space 111 of the chamber 110 is converted from the atmospheric conditions to the vacuum conditions, the second holder 122 may move in the second direction DR2, approaching the electrostatic chuck 140, by the distance moved at the displacement difference measurement operation (i.e., the fourth displacement difference DD4), and be located at the target position TP. As described above, the target position TP may be an optimized position of the second holder 122 to enable the substrate SUB to be stably seated on the electrostatic chuck 140. Consequently, during a process in which the substrate SUB is adsorbed to the electrostatic chuck 140, the substrate SUB may be prevented from being damaged or broken.

If the position of the second holder 122 is not adjusted to the position ADJ away from the electrostatic chuck 140 through the aforementioned position adjustment operation, the second holder 122 may be located at a position CP closer to the electrostatic chuck 140 than the target position TP at the deposition operation. In this case, during a process in which the substrate SUB and the electrostatic chuck 140 approach each other, the substrate SUB and the electrostatic chuck 140 may already come into contact with each other before power is applied to the electrostatic chuck 140 to attract the substrate SUB using electrostatic force, resulting in unintended physical force being applied to the substrate SUB, thus causing the substrate SUB to be damaged or broken.

In this way, after the position variation (i.e., the displacement difference DD) of the second holder 122 due to a change in pressure conditions of the internal space 111 of the chamber 110 is measured at the displacement difference measurement operation, the position of the second holder 122 is adjusted at the position adjustment operation. Accordingly, a phenomenon in which unintended pressure applied to the substrate SUB before or after the substrate SUB is adsorbed to the electrostatic chuck 140 during the deposition process causes the substrate SUB to be damaged or broken may be mitigated.

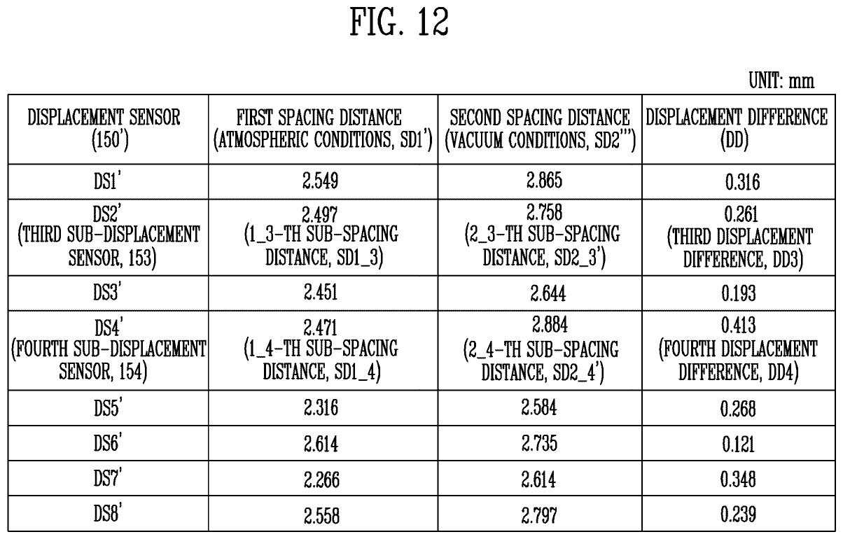

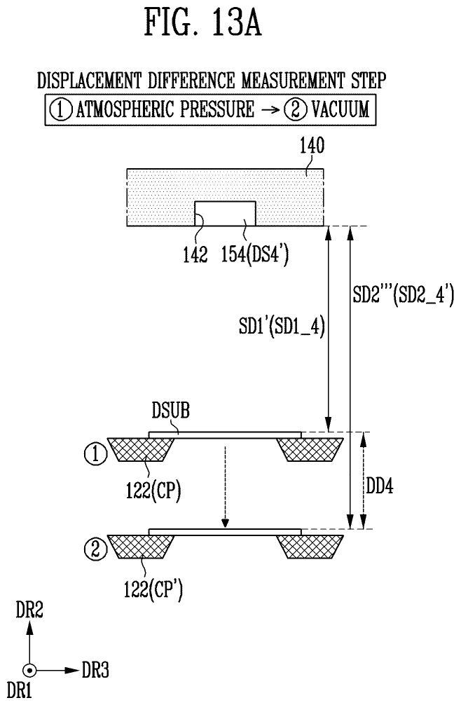

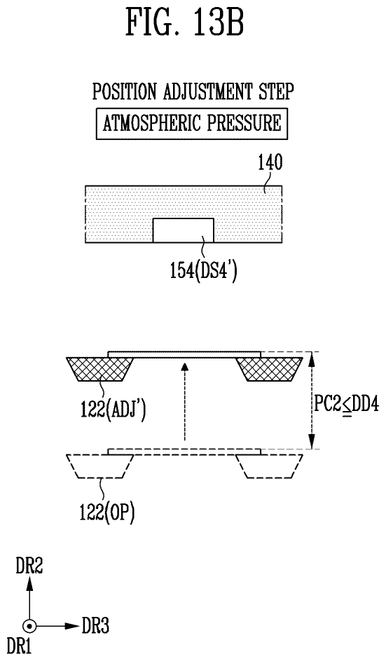

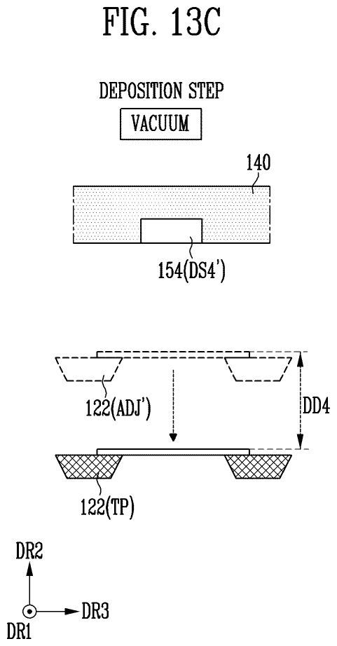

FIG. 12 is a table showing a modification of the first spacing distances and the second spacing distances shown in FIG. 10, and the displacement differences calculated therefrom. FIG. 13A is a conceptual diagram illustrating a modification of FIG. 11A. FIG. 13B is a conceptual diagram illustrating a modification of FIG. 11B. FIG. 13C is a conceptual diagram illustrating a modification of FIG. 11C.

Displacement sensors 150′, a first spacing distance SD1′, a second spacing distance SD2′″, and a displacement difference DD that are shown in FIG. 12 may be formed in the same manner as the displacement sensors 150, the first spacing distance SD1′, the second spacing distance SD2″, and the displacement difference DD that are described with reference to FIG. 10. Hereinafter, redundant descriptions will be omitted.

Referring to FIG. 12, measured by each of the displacement sensors 150, the second spacing distance SD2′″ may be greater than the first spacing distance SD1′.

For example, in the case where the internal space 111 of the chamber 110 is under atmospheric conditions, the 1_3-th sub-spacing distance SD1_3 measured by the third sub-displacement sensor DS2′ is 2.497 mm. In this state, in the case where the internal space 111 of the chamber 110 is converted to vacuum conditions, the 2_3-th sub-spacing distance SD2_3 measured by the third sub-displacement sensor DS2′ is 2.758 mm. In other words, in the case where the internal space 111 of the chamber 110 is converted from the atmospheric conditions to the vacuum conditions, compared to the first spacing distance SD1′ measured by the third sub-displacement sensor DS2′ the second spacing distance SD2′″ may be increased by a third displacement difference DD3. The foregoing indicates that in the case where the internal space 111 of the chamber 110 is converted from the atmospheric conditions to the vacuum conditions, the first holder 121 may move in a direction away from the third sub-displacement sensor DS2′ by a third displacement difference DD3 of 0.261 mm compared to the position thereof when under the atmospheric conditions.

FIG. 13A illustrates a displacement difference measurement operation of measuring the first spacing distance SD1′ between the second sub-displacement sensor DS4′ and the second holder 122 in state \textcircled{1} in which the internal space 111 of the chamber 110 is under the atmospheric conditions, and measuring the second spacing distance SD2′″ between the fourth sub-displacement sensor DS4′ and the second holder 122 in state \textcircled{2} in which the internal space 111 has been converted to the vacuum conditions.

Referring to FIGS. 12 and 13A together, in the case where the internal space 111 of the chamber 110 is under the atmospheric conditions, the 1_4-th sub-spacing distance SD1_4 measured by the fourth sub-displacement sensor DS4′ is 2.471 mm. Here, the position OP of the second holder 122 may be a position optimized (or targeted) to enable the substrate SUB to be stably seated on the electrostatic chuck 140 during a process of adsorbing the substrate SUB to the electrostatic chuck 140 to perform a deposition operation. Given this, the position OP of the second holder 122 illustrated in FIG. 13A may refer to “original position” of the second holder 122 in the case where the internal space 111 of the chamber 110 is under the atmospheric conditions, and may also be referred to as “target position TP” to be described with reference to FIG. 13C.

In this state, in the case where the internal space 111 of the chamber 110 is converted to the vacuum conditions, a 2_4-th sub-spacing distance SD2_4′ measured by the fourth sub-displacement sensor DS4′ is 2.884 mm. In other words, in the case where the internal space 111 of the chamber 110 is converted from the atmospheric conditions to the vacuum conditions, the 2_4-th sub-spacing distance SD2_4′ may be increased by a fourth displacement difference DD4 compared to the 1_4-th sub-spacing distance SD1_4. The foregoing indicates that in the case where the internal space 111 of the chamber 110 is converted from the atmospheric conditions to the vacuum conditions, the second holder 122 may move to a position CP′ more distant from the fourth sub-displacement sensor DS4′ by a fourth displacement difference DD4 of 0.413 mm compared to the position OP thereof when under the atmospheric conditions.

As such, each of the displacement sensors 150′ may measure one first spacing distance SD1′ and one second spacing distance SD2′″. A plurality of displacement differences DD may be derived by calculating differences between the respective first spacing distances SD1′ and the corresponding second spacing distances SD2′″. Among the displacement differences DD, the controller 160 may select one displacement difference DD having the largest value. For example, because the fourth displacement difference DD4 measured by the fourth sub-displacement sensor DS4′ is 0.413 mm, which is larger than any one of the displacement differences DD measured by the other displacement sensors DS1′ to DS3′ and DS5′ to DS8′, the fourth displacement difference DD4 may be selected as a displacement difference DD that is a basis for adjusting the position of the substrate support 120 to be described later.

FIG. 13B illustrates a position adjustment operation of adjusting the position of the substrate support 120, based on the fourth displacement difference DD4 calculated and selected through the displacement difference measurement operation described above. Referring to FIG. 13B, in the state where the internal space 111 of the chamber 110 is under the atmospheric conditions, the position of the second holder 122 may be adjusted from the original position OP by a fourth position variation PC2 in a direction approaching the electrostatic chuck 140, in other words, in the second direction DR2 (i.e., OP→ADJ′).

As such, in the case where the second spacing distance SD2′″ is greater than the first spacing distance SD1′, the controller 160 may adjust the position of the substrate support 120 (i.e., including the positions of the first and second holders 121 and 122 and the first and second brackets 123 and 124, which are sub-elements of the substrate support 120) by the fourth position variation PC2 in a direction approaching the electrostatic chuck 140.

Here, the fourth position variation PC2 may be smaller than or equal to the fourth displacement difference DD4 that is calculated and selected at the displacement difference measurement operation. As a result, at a deposition operation to be described later with reference to FIG. 13C, the substrate SUB may be positioned closer to the electrostatic chuck 140 than the target position TP, thereby preventing the substrate SUB from being damaged or broken due to excessive pressure during the adsorption operation of the substrate SUB and the electrostatic chuck 140.

FIG. 13C illustrates conversion of the conditions of the internal space 111 of the chamber 110 from the atmospheric conditions to the vacuum conditions so as to enable the deposition apparatus 100 to perform a deposition process.

In the case where the internal space 111 of the chamber 110 is converted from the atmospheric conditions to the vacuum conditions, the second holder 122 may move in the opposite direction to the second direction DR2, i.e., in a direction away from the electrostatic chuck 140, by the distance moved at the displacement difference measurement operation (i.e., the fourth displacement difference DD4), and be located at the target position TP. As described above, the target position TP may be an optimized position of the second holder 122 to enable the substrate SUB to be stably seated on the electrostatic chuck 140. Consequently, during a process in which the substrate SUB is adsorbed to the electrostatic chuck 140, the substrate SUB may be prevented from being damaged or broken.

If the position of the second holder 122 is not adjusted to the position ADJ′ approaching the electrostatic chuck 140 through the aforementioned position adjustment operation, the second holder 122 may be located at a position CP′ more distant from the target position TP. In this case, during a process in which the substrate SUB and the electrostatic chuck 140 approach each other, even if power is applied to the electrostatic chuck 140, the minimum distance required for the substrate SUB to be adsorbed to the electrostatic chuck 140 may not be secured.

In this way, after the position variation (i.e., the displacement difference DD) of the second holder 122 due to a change in pressure conditions of the internal space 111 of the chamber 110 is measured at the displacement difference measurement operation, the position of the second holder 122 is adjusted at the position adjustment operation. Accordingly, the minimum distance required for the substrate SUB to be sufficiently adsorbed to the electrostatic chuck 140 during the deposition process may be secured.

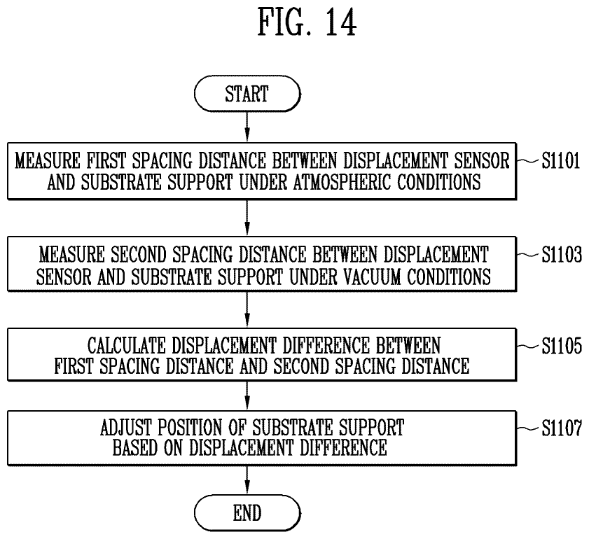

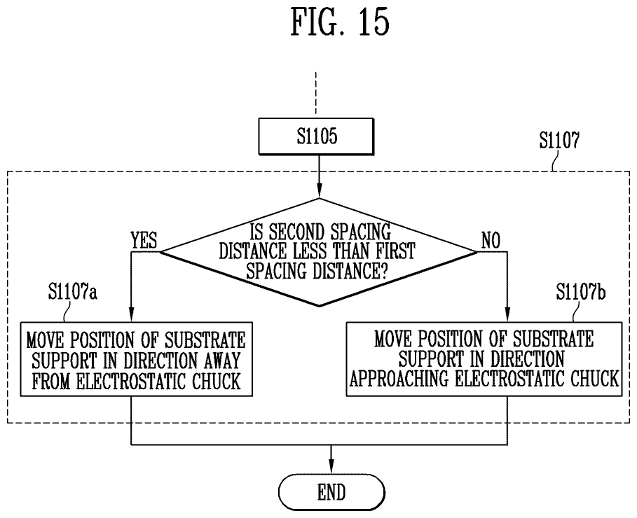

FIG. 14 is a flowchart showing a method of driving the deposition apparatus 100 illustrated in FIG. 1. Although FIG. 14 illustrates various operations in a method of driving a deposition apparatus, embodiments according to the present disclosure are not limited thereto, and according to various embodiments, the method may include additional operations, or fewer operations, or the order of operations may vary, unless otherwise stated or implied, without departing from the spirit and scope of embodiments according to the present disclosure. FIG. 15 is a flowchart showing further details of the operation S1107 of FIG. 14. Although FIG. 15 illustrates various operations in a method of driving a deposition apparatus, embodiments according to the present disclosure are not limited thereto, and according to various embodiments, the method may include additional operations, or fewer operations, or the order of operations may vary, unless otherwise stated or implied, without departing from the spirit and scope of embodiments according to the present disclosure.

Hereinafter, the method of driving the deposition apparatus 100 will be described with reference to FIGS. 14 and 15. Components and conditions mentioned in describing each operation may be configured in the same manner as the respective components and conditions of the deposition apparatus 100 described with reference to FIGS. 1 to 13. Therefore, in the following description, redundant explanations of the arrangement, coupling relationships, and detailed characteristics of the components will be omitted.

Referring to FIG. 14, in operation S1101, the deposition apparatus 100 in accordance with embodiments may measure a first spacing distance SD1 or SD1′ between the displacement sensor 150 or 150′ and the substrate support 120 under the atmospheric conditions.

According to some embodiments, as described with reference to FIGS. 4, 6, 10, 11, 12, and 13, in the state in which the internal space 111 of the chamber 110 is under the atmospheric conditions, the first spacing distance SD1 or SD1′ may refer to a distance between the first sub-displacement sensor 151 and the first holder 121, between the second sub-displacement sensor 152 and the second holder 122, between the third sub-displacement sensor 153 and the dummy substrate DSUB, and/or between the fourth sub-displacement sensor 154 and the dummy substrate DSUB.

In operation S1103, the deposition apparatus 100 in accordance with embodiments may measure a second spacing distance SD2, SD2′, SD2″, and SD2′″ between the displacement sensor 150 and the substrate support 120 under the vacuum conditions.

According to some embodiments, as described with reference to FIGS. 4, 6, 10, 11, 12, and 13, in the state in which the internal space 111 of the chamber 110 has been converted from the atmospheric conditions to the vacuum conditions, the second spacing distance SD2, SD2′, SD2″, or SD2′″ may refer to a distance between the first sub-displacement sensor 151 and the first holder 121, between the second sub-displacement sensor 152 and the second holder 122, between the third sub-displacement sensor 153 and the dummy substrate DSUB, and/or between the fourth sub-displacement sensor 154 and the dummy substrate DSUB.

In operation S1105, the deposition apparatus 100 in accordance with embodiments may calculate displacement differences DD between the first spacing distance SD1 or SD1′ and the second spacing distance SD2, SD2′, SD2″, and SD2′″ that are respectively measured in operations S1101 and S1103.

According to some embodiments, the displacement difference DD may refer to a difference value between the first spacing distance SD1 or SD1′ and the second spacing distance SD2, SD2′, SD2″, and SD2′″ that are respectively measured by the displacement sensors 150 and 150′, as described with reference to FIGS. 4, 6, 10, and 12. As described above, among the displacement differences DD, the controller 160 may select one displacement difference DD having the largest value.

In operation S1107, the deposition apparatus 100 in accordance with embodiments may adjust the position of the substrate support 120 based on the displacement difference DD calculated in operation S1105.

Referring to FIG. 15, before adjusting the position of the substrate support 120, the controller 160 may perform an operation of comparing the values of the first spacing distance SD1 or SD2′ and the second spacing distance SD2, SD2′, SD2″, and SD2′″ used to derive the selected one displacement difference DD. For example, the controller 160 may determine whether the second spacing distance SD2, SD2′, SD2″, or SD2′″ is smaller than the first spacing distance SD1 or SD1′.

According to some embodiments, as illustrated in FIGS. 4, 5, 10, and 11, in the case where the second spacing distance SD2, SD2′, SD2″, or SD2′″ is smaller than the first spacing distance SD1 or SD1′, the controller 160 may respectively transmit a first driving signal DRS1 and a second driving signal DRS2 to the first sub-driver 131 and the second sub-driver 132 to move the position of the substrate support 120 in a direction away from the electrostatic chuck 140, as illustrated in FIG. 3.

As in operation S1107a, in response to the first driving signal DRS1 and the second driving signal DRS2, the first sub-driver 131 and the second sub-driver 132 may respectively move the first holder 121 and the second holder 122 in the direction away from the electrostatic chuck 140 by the first position variation PC1 equal to or greater than the second displacement difference DD2 or the fourth displacement difference DD4 (refer to FIGS. 5 and 11).

According to some embodiments, as illustrated in FIGS. 6, 7, 12, and 13, in the case where the second spacing distance SD2, SD2′, SD2″, or SD2′″ is greater than the first spacing distance SD1 or SD1′, the controller 160 may respectively transmit a first driving signal DRS1 and a second driving signal DRS2 to the first sub-driver 131 and the second sub-driver 132 to move the position of the substrate support 120 in a direction approaching the electrostatic chuck 140, as illustrated in FIG. 3.

As in operation S1107b, in response to the first driving signal DRS1 and the second driving signal DRS2, the first sub-driver 131 and the second sub-driver 132 may respectively move the first holder 121 and the second holder 122 in the direction approaching the electrostatic chuck 140 by the second position variation PC2 equal to or less than the second displacement difference DD2 or the fourth displacement difference DD4 (refer to FIGS. 7 and 13).

In a deposition apparatus and a method of driving the deposition apparatus in accordance with embodiments of the present disclosure, even when an internal space of a chamber is converted from atmospheric conditions to vacuum conditions, positions of holders supporting a substrate may be uniformly aligned at target positions. For example, before the operation of processing the substrate, in the case where the internal environment of the chamber is converted to atmospheric pressure to vacuum, position variation of the holders may be measured and reflected in previous setting positions of the holders under the atmospheric conditions. Consequently, at the operation of bringing the substrate into close contact with an electrostatic chuck after the atmospheric environment is converted to the vacuum environment to process the substrate, instances of the substrate being broken or damaged may be prevented or relatively reduced, or the minimum distance required to adsorb the substrate to the electrostatic chuck may be secured.

However, the characteristics of embodiments according to the present disclosure are not limited to the above-described characteristics, and various modifications are possible without departing from the spirit and scope of embodiments according to the present disclosure.

A display device fabricated by the deposition apparatus and the method of driving the deposition apparatus in accordance with embodiments of the present disclosure is applicable to various types of electronic devices. In an embodiment, an electronic device includes the above-described display device and may further include other modules or devices having additional functions in addition to the display device.

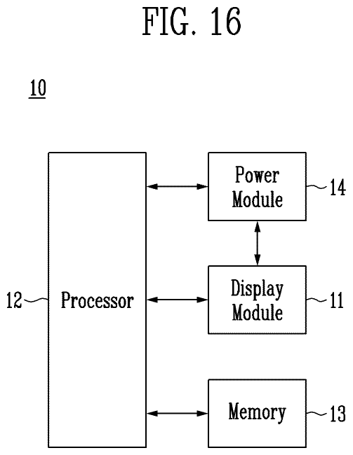

FIG. 16 is a block diagram of an electronic device according to an embodiment. Referring to FIG. 16, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

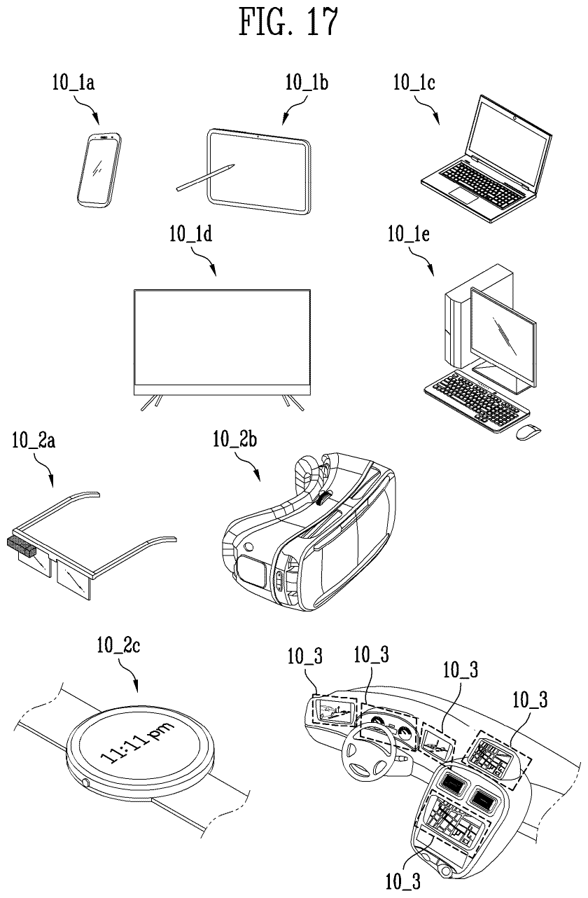

FIG. 17 shows schematic views of various embodiments of an electronic device.

Referring to FIG. 17, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

Although specific embodiments and application examples have been described, it should be noted that other embodiments and modifications may be derived from the disclosure provided. Accordingly, the present disclosure is not limited to the foregoing embodiments, but may extend to the appended claims, and their equivalents.

What is claimed is:

1. A deposition apparatus comprising:
a chamber including an internal space settable to either atmospheric conditions or vacuum conditions;
a substrate support in the internal space of the chamber and configured to support a substrate;
a first driver configured to reciprocate the substrate support in a first direction and a direction opposite to the first direction;
an electrostatic chuck spaced apart from the substrate support in the first direction;
a displacement sensor installed in the electrostatic chuck, and configured to measure a first spacing distance from the substrate support under the atmospheric conditions and a second spacing distance from the substrate support under the vacuum conditions; and
a controller configured to adjust a position of the substrate support based on a displacement difference between the first spacing distance and the second spacing distance.

2. The deposition apparatus according to claim 1, wherein based on the second spacing distance being less than the first spacing distance, the controller is configured to adjust the position of the substrate support in a direction away from the electrostatic chuck.

3. The deposition apparatus according to claim 2, wherein a position variation of the substrate support is equal to or greater than the displacement difference.

4. The deposition apparatus according to claim 1, wherein based on the second spacing distance being greater than the first spacing distance, the controller is configured to adjust the position of the substrate support in a direction approaching the electrostatic chuck.

5. The deposition apparatus according to claim 4, wherein the position variation of the substrate support is less than or equal to the displacement difference.

6. The deposition apparatus according to claim 1, wherein the substrate support comprises:
a plurality of first holders configured to support a first area of the substrate;
and a plurality of second holders configured to support a second area of the substrate distinct from the first area.

7. The deposition apparatus according to claim 6,
wherein the displacement sensor comprises:
a first sub-displacement sensor overlapping at least one of the first holders in a plan view; and
a second sub-displacement sensor overlapping at least one of the second holders in a plan view,
wherein the first spacing distance includes:
a 1_1-th sub-spacing distance measured by the first sub-displacement sensor and defined between the first sub-displacement sensor and the first holder; and
a 1_2-th sub-spacing distance measured by the second sub-displacement sensor and defined between the second sub-displacement sensor and the second holder,
wherein the second spacing distance includes:
a 2_1-th sub-spacing distance measured by the first sub-displacement sensor and defined between the first sub-displacement sensor and the first holder; and
a 2_2-th sub-spacing distance measured by the second sub-displacement sensor and defined between the second sub-displacement sensor and the second holder, and
wherein the displacement difference is a larger value between a first displacement difference between the 1_1-th sub-spacing distance and the 2_1-th sub-spacing distance and a second displacement difference between the 1_2-th sub-spacing distance and the 2_2-th sub-spacing distance.

8. The deposition apparatus according to claim 7,
wherein the substrate support further comprises:
a first bracket on which the first holders are located; and
a second bracket on which the second holders are located, and
wherein the first driver comprises:
a first sub-driver connected to the first bracket; and
a second sub-driver connected to the second bracket.

9. The deposition apparatus according to claim 8,
wherein the controller is configured to transmit a first driving signal derived based on the displacement difference to the first sub-driver, and to transmit a second driving signal derived based on the displacement difference to the second sub-driver,
wherein the first sub-driver is configured to move the first bracket in the first direction or the direction opposite to the first direction based on the first driving signal, and
wherein the second sub-driver is configured to move the second bracket in the first direction or the direction opposite to the first direction based on the second driving signal.

10. The deposition apparatus according to claim 6, wherein the displacement sensor comprises:
a third sub-displacement sensor configured not to overlap the first holders in a plan view; and
a fourth sub-displacement sensor configured not to overlap the second holders in a plan view.

11. The deposition apparatus according to claim 10,
wherein the first spacing distance includes:
a 1_3-th sub-spacing distance measured by the third sub-displacement sensor and defined between the third sub-displacement sensor and one area of a dummy substrate on the first holder; and
a 1_4-th sub-spacing distance measured by the fourth sub-displacement sensor and defined between the fourth sub-displacement sensor and another area of the dummy substrate on the second holder, and
wherein the second spacing distance includes:
a 2_3-th sub-spacing distance measured by the third sub-displacement sensor and defined between the third sub-displacement sensor and one area of the dummy substrate on the first holder; and
a 2_4-th sub-spacing distance measured by the fourth sub-displacement sensor and defined between the fourth sub-displacement sensor and another area of the dummy substrate on the second holder.

12. The deposition apparatus according to claim 11, wherein the displacement difference is a larger value between a third displacement difference between the 1_3-th sub-spacing distance and the 2_3-th sub-spacing distance and a fourth displacement difference between the 1_4-th sub-spacing distance and the 2_4-th sub-spacing distance.

13. The deposition apparatus according to claim 1, further comprising a pressing component configured to press a lower side of the substrate,
wherein the pressing component comprises:
a plurality of first pusher pins configured to press a portion of the substrate, and
a plurality of second pusher pins configured to press another portion of the substrate.

14. The deposition apparatus according to claim 13, further comprising a second driver configured to reciprocate the pressing component in the first direction and the direction opposite to the first direction,
wherein the pressing component comprises:
a third bracket on which the first pusher pins are located; and
a fourth bracket on which the second push pins are located, and
wherein the second driver comprises:
a third sub-driver connected to the third bracket; and
a fourth sub-driver connected to the fourth bracket.

15. A method of driving a deposition apparatus, comprising:
measuring a first spacing distance between a substrate support and a displacement sensor installed in an electrostatic chuck under atmospheric conditions;
measuring a second spacing distance between the substrate support and the displacement sensor installed in the electrostatic chuck under vacuum conditions;
calculating a displacement difference between the first spacing distance and the second spacing distance; and
adjusting a position of the substrate support based on the displacement difference.

16. The method according to claim 15, wherein adjusting the position of the substrate support comprises moving the position of the substrate support in a direction away from the electrostatic chuck in a case where the second spacing distance is less than the first spacing distance.

17. The method according to claim 16, wherein a position variation of the substrate support is equal to or greater than the displacement difference.

18. The method according to claim 15, wherein adjusting the position of the substrate support comprises moving the position of the substrate support in a direction approaching the electrostatic chuck in a case where the second spacing distance is greater than the first spacing distance.

19. The method according to claim 18, wherein a position variation of the substrate support is less than or equal to the displacement difference.

20. A electronic device, comprising:
a processor; and
a display device including pixels, and configured to display images on the pixels under control of the processor;
wherein the display device is fabricated by the method of driving a deposition apparatus according to claim 15.
